(19) United States
(12) Patent Application Publication
(10) Pub. No.: US 2024/0234261 A1
(43) Pub. Date: Jul. 11, 2024

(54) SEMICONDUCTOR DEVICE

(71) Applicant: FUJI ELECTRIC CO., LTD., Kawasaki-shi (JP)

(72) Inventor: Masaharu YAMAJI, Matsumoto-city (JP)

(73) Assignee: FUJI ELECTRIC CO., LTD., Kawasaki-shi (JP)

(21) Appl. No.: 18/523,157

(22) Filed: Nov. 29, 2023

(30) Foreign Application Priority Data
Jan. 11, 2023 (JP) 2023-002682

(51) Int. Cl. H01L 23/495; H01L 23/00; H01L 25/065

(52) U.S. Cl. CPC H01L 23/4952; H01L 23/4951; H01L 23/49575; H01L 24/33; H01L 24/48; H01L 25/0652; H01L 2224/3301; H01L 2224/33515; H01L 2224/48091; H01L 2224/48227; H01L 2224/48247; H01L 2924/01029; H01L 2924/13055; H01L 2924/1427

(57) ABSTRACT

A semiconductor device includes a plurality of power semiconductor elements and a control chip including a plurality of terminals including a first terminal and a plurality of second terminals and configured to control the plurality of power semiconductor elements, using power supply voltage supplied to the plurality of second terminals. The semiconductor device also includes a first conductor for supplying a predetermined control voltage to the first terminal, a plurality of first wirings individually connected to the plurality of second terminals and for supplying the power supply voltage to the plurality of the second terminals, a die pad on which the control chip is arranged, and a semiconductor chip including a diode used for bootstrap operation to generate the power supply voltage. The semiconductor chip is fixed to the die pad by an insulating material. The die pad is connected to a terminal to which a reference voltage is supplied.

### TECHNICAL FIELD

The present disclosure relates to a semiconductor device.

### BACKGROUND ART

As a semiconductor device according to prior art, a semiconductor device including a switching element and a bootstrap diode and capable of performing power conversion has been known (e.g., Patent Documents 1 and 2).

### CITATION LIST

### Patent Document

Patent Document 1: WO 2014/199608 A1
Patent Document 2: JP 2019-192833 A

### SUMMARY OF INVENTION

### Technical Problem

Recent years, while industrial equipment and household appliances have increasingly been made highly efficient as inverters have become widely used, miniaturization of a power conversion unit including a control unit to control a switching element and a bootstrap diode has been demanded. In a configuration in which a control unit and a bootstrap diode are arranged on the same die pad in order to achieve miniaturization, there is a possibility that a voltage exceeding a dielectric withstand voltage of the control unit and the die pad is applied to the control unit caused by noise input to the control unit and as a result, the semiconductor device malfunctions.

An object of the present disclosure is to provide a semiconductor device capable of, while preventing noise resistance from deteriorating, achieving miniaturization.

### Solution to Problem

In order to solve the above-described problem, a semiconductor device according to one aspect of the present disclosure includes a plurality of power semiconductor elements and a control chip including a plurality of terminals including a first terminal and a plurality of second terminals and configured to control the plurality of power semiconductor elements, using power supply voltage supplied to the plurality of second terminals. The semiconductor device also includes a first conductor configured to supply a predetermined control voltage to the first terminal, a plurality of first wirings individually connected to the plurality of second terminals and for supplying the power supply voltage to the plurality of the second terminals, a die pad on which the control chip is arranged, and a semiconductor chip including a diode used for bootstrap operation to generate the power supply voltage. The semiconductor chip is fixed to the die pad by an insulating material. The die pad is connected to a terminal to which a reference voltage is supplied.

### Advantageous Effects of Invention

According to the one aspect of the present disclosure, it is possible to, while preventing noise resistance from deteriorating, achieve miniaturization.

### BRIEF DESCRIPTION OF DRAWINGS

FIG. 1 is a circuit diagram illustrative of an electrical configuration of a semiconductor device according to a first embodiment of the present disclosure.

FIG. 2 is a layout diagram illustrative of an arrangement of respective elements included in the semiconductor device according to the first embodiment of the present disclosure.

FIG. 3 is a layout diagram illustrative of a vicinity of semiconductor chips and high-potential-side drive chips included in the semiconductor device in an enlarged manner according to the first embodiment of the present disclosure.

FIG. 4 is a plan view illustrative of a configuration example of one of the semiconductor chips included in the semiconductor device according to the first embodiment of the present disclosure.

FIG. 5 is a cross-sectional view of the semiconductor chip taken along the line A-A′ illustrated in FIG. 4.

FIG. 6 is a cross-sectional view illustrative of an arrangement and connections of the semiconductor chips included in the semiconductor device according to the first embodiment of the present disclosure.

FIG. 7 is a plan view illustrative of a configuration of a high-potential-side control chip included in the semiconductor device according to the first embodiment of the present disclosure.

FIG. 8 is a cross-sectional view of the high-potential-side control chip taken along the line C-C′ illustrated in FIG. 7.

FIG. 9 is a circuit diagram illustrative of an electrical configuration of a semiconductor device according to a second embodiment of the present disclosure.

FIG. 10 is a layout diagram illustrative of an arrangement of respective elements included in the semiconductor device according to the second embodiment of the present disclosure.

FIG. 11 is a layout diagram illustrative of a vicinity of a semiconductor chip and high-potential-side drive chips included in the semiconductor device in an enlarged manner according to the second embodiment of the present disclosure.

FIG. 12 is a cross-sectional view of the semiconductor chip taken along the line C-C′ illustrated in FIG. 11.

### DESCRIPTION OF EMBODIMENTS

Embodiments for embodying the present disclosure will be described with reference to the drawings. Note that in each drawing, dimensions and a scale of each element are sometimes different from those of an actual product. Further, embodiments that will be described below are exemplary embodiments that are supposed to be embodied in the case where the present disclosure is implemented. Therefore, the scope of the present disclosure is not limited to the embodiments exemplified below.

### A: First Embodiment

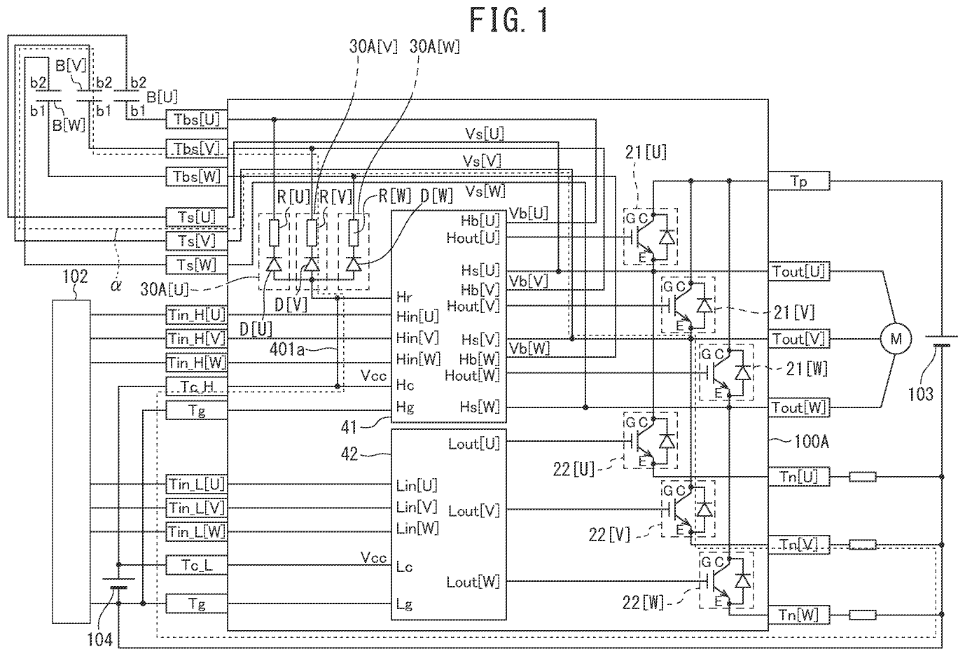

FIG. 1 is a circuit diagram illustrative of an electrical configuration of a semiconductor device 100A according to the present embodiment. The semiconductor device 100A is an intelligent power module that is used as a three-phase inverter circuit configured to drive a motor M, such as a three-phase motor. To the semiconductor device 100A, a control device 102 is connected. The control device 102 is, for example, an external micro processing unit (MPU) configured to control operation of the semiconductor device 100A.

Note that in the following description, an arbitrary AC phase in the motor M is identified by a symbol k. That is, the symbol k means any one of a U-phase, a V-phase, and a W-phase (k=U, V, or W). For example, a sign [k] appended to a reference sign means that an element indicated by the reference sign is an element corresponding to each AC phase of the motor M. As exemplarily illustrated in FIG. 1, the semiconductor device 100A includes a plurality of connection terminals T for external connections (Tin_H[k], Tin_L[k], Tout[k], Tc_H, Tc_L, Tg, Tp, Tn[k], and Tbs[k]).

The semiconductor device 100A includes three drive chips 21[k] (21[U], 21[V], and 21[W]), three drive chips 22[k] (22[U], 22[V], and 22[W]), three semiconductor chips 30A[k] (30A[U], 30A[V], and 30A[W]), a control chip 41, and a control chip 42. With respect to each of the three phases (the U-phase, the V-phase, and the W-phase) of the motor M, a drive chip 21[k], a drive chip 22[k], and a semiconductor chip 30A[k] are installed.

Each of the drive chips 21[k] and the drive chips 22[k] is a reverse conducting (RC)-insulated gate bipolar transistor (IGBT) including an IGBT and a free wheeling diode (FWD) and includes a main electrode E, a main electrode C, and a control electrode G. The main electrode E and the main electrode C are electrodes to or from which current to be controlled is input or output. The main electrode C also functions as a cathode of the FWD, and the main electrode E also functions as an anode of the FWD. The control electrode G is a gate electrode to which drive voltage for controlling ON/OFF of the IGBT is applied. Note that each of the drive chips 21[k] and the drive chips 22[k] is an example of a “power semiconductor element”. In other words, the semiconductor device 100A includes a plurality of power semiconductor elements.

Each pair of a drive chip 21[k] and a drive chip 22[k] constitutes a half-bridge circuit corresponding to one of the AC phases of the motor M. Each pair of a drive chip 21[k] and a drive chip 22[k] is connected in series between a connection terminal Tp and a corresponding one of connection terminals Tn[k]. A connection point between each pair of a drive chip 21[k] and a drive chip 22[k] is electrically connected to a corresponding one of connection terminals Tout[k]. Each of the connection terminals Tout[k] is an output terminal for supplying power to one of the AC phases of the motor M. To the connection terminal Tp, high-potential-side power supply voltage is supplied from an external power supply 103. To each of the connection terminals Tn[k], low-potential-side power supply voltage (ground voltage) is supplied. Note that the three connection terminals Tn[k] may be replaced by a single terminal common to the three phases.

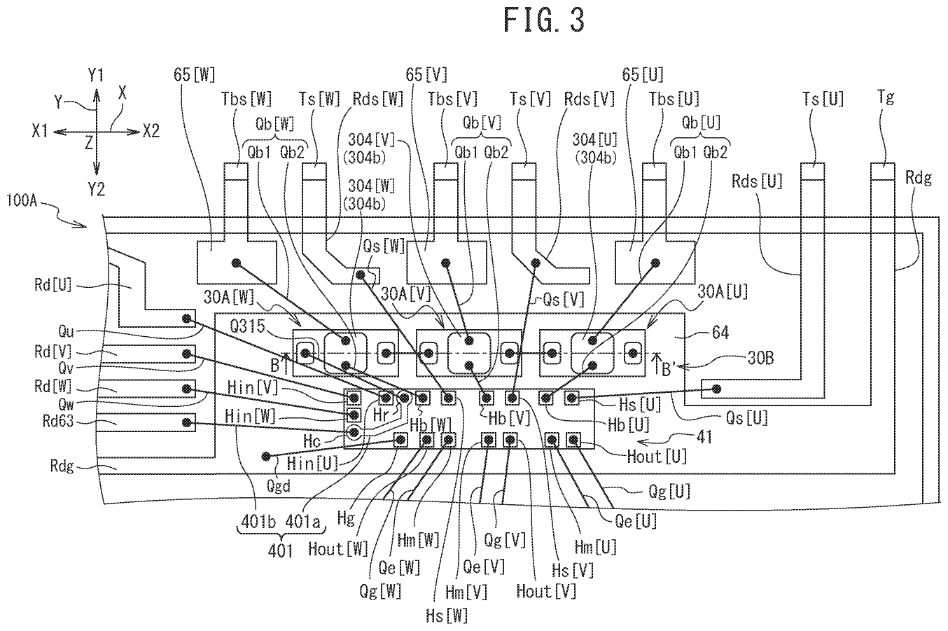

The control chip 41 is a high voltage IC (HVIC) configured to control each of the high-potential-side drive chips 21[k]. As exemplarily illustrated in FIG. 1, the control chip 41 includes a plurality of terminals H (Hin[k], Hout[k], Hb[k], Hs[k], Hm[k] (not illustrated in FIG. 1, see FIG. 3), Hc, Hg, and Hr). That is, the control chip 41 includes, with respect to each AC phase of the motor M, an input terminal Hin[k], an output terminal Hout[k], a power supply terminal Hb[k], a power supply terminal Hs[k], and a middle terminal Hm[k] (not illustrated in FIG. 1, see FIG. 3).

A control signal supplied from the control device 102 to each connection terminal Tin_H[k] is input to a corresponding one of the input terminals Hin[k]. Each of the control signals is a signal for controlling a corresponding one of the drive chips 21[k]. To each of the power supply terminals Hb[k], a corresponding one of high-potential-side power supply voltages Vb[k] is supplied, and to each of the power supply terminals Hs[k], a corresponding one of low-potential-side power supply voltages Vs[k] is supplied. The control chip 41 operates with power supply voltages supplied to the power supply terminals Hb[k] and the power supply terminals Hs[k] and thereby outputs a drive voltage matching each control signal supplied to a corresponding one of the input terminals Hin[k] to a corresponding one of the output terminals Hout[k]. Each of the output terminals Hout[k] is electrically connected to the control electrode G of the IGBT in a corresponding one of the drive chips 21[k]. As understood from the above description, the control chip 41 controls each of the drive chips 21[k], using a corresponding one of the power supply voltages Vb[k] supplied to a corresponding one of the power supply terminals Hb[k]. The power supply terminals Hb[k] are an example of “second terminals”.

Further, the control chip 41 includes a voltage terminal Hc, a ground terminal Hg, and a relay terminal Hr. To the voltage terminal Hc, control voltage Vcc is supplied from an external power supply 104 via a connection terminal Tc_H. The relay terminal Hr is connected to the voltage terminal Hc by a relay pattern 401a. The control voltage Vcc is a predetermined DC voltage to be used for operation of the control chip 41. Further, the control voltage Vcc is also used for bootstrap operations to generate the power supply voltages Vb[k] of the control chip 41. On the other hand, the ground terminal Hg is grounded. Note that the voltage terminal Hc is an example of a “first terminal”.

Therefore, the semiconductor device 100A includes the control chip 41 including the terminals H (Hin[k], Hout[k], Hb[k], Hs[k], Hm[k], Hc, Hg, and Hr) (an example of a plurality of terminals) that includes the voltage terminal Hc (an example of the first terminal) and the power supply terminals Hb[U], Hb[V], and Hb[W] (an example of a plurality of second terminals).

The control chip 42 is a low voltage IC (LVIC) configured to control each of the low-potential-side drive chips 22[k]. Further, the control chip 41 and the control chip 42 may be formed as a single chip. As exemplarily illustrated in FIG. 1, the control chip 42 includes a plurality of terminals L (Lin[k], Lout[k], Lc, and Lg). That is, the control chip 42 includes, with respect to each AC phase of the motor M, an input terminal Lin[k] and an output terminal Lout[k].

A control signal supplied from the control device 102 to each connection terminal Tin_L[k] is input to a corresponding one of the input terminals Lin[k]. Each of the control signals is a signal for controlling a corresponding one of the drive chips 22[k]. The control chip 42 outputs drive voltage matching a control signal supplied to each of the input terminals Lin[k] to a corresponding one of the output terminals Lout[k]. Each of the output terminals Lout[k] is electrically connected to the control electrode G of the IGBT in a corresponding one of the drive chips 22[k]. That is, the control chip 42 controls each of the drive chips 22[k].

Further, the control chip 42 includes a voltage terminal Lc and a ground terminal Lg. To the voltage terminal Lc, the control voltage Vcc is supplied from the external power supply 104 via a connection terminal Tc_L. Note that the control voltage Vcc supplied to the control chip 41 and the control voltage Vcc supplied to the control chip 42 may differ from each other. On the other hand, the ground terminal Lg is grounded.

As exemplarily illustrated in FIG. 1, each of the power supply terminals Hb[k] of the control chip 41 is electrically connected to a corresponding one of connection terminals Tbs[k]. Between each of the connection terminals Tbs[k] and a corresponding one of connection terminals Ts[k], a capacitance element B[k] is electrically connected. Each of the capacitance elements B[k] is a bootstrap capacitor that is externally connected to the semiconductor device 100A. Each of the capacitance elements B[k] includes a first electrode b1 and a second electrode b2. The first electrode b1 is electrically connected to a corresponding one of the connection terminals Tbs[k], and the second electrode b2 is electrically connected to a corresponding one of the connection terminals Ts[k].

Each of the semiconductor chips 30A[k] (for example, 30A[U], 30A[V], and 30A[W]) is connected to the connection terminal Tc_H and a corresponding one of the connection terminals Tbs[k]. That is, each of the semiconductor chips 30A[k] is connected to the voltage terminal Hc and a corresponding one of the power supply terminals Hb[k] of the control chip 41. The semiconductor chips 30A[k] are used for the aforementioned bootstrap operation.

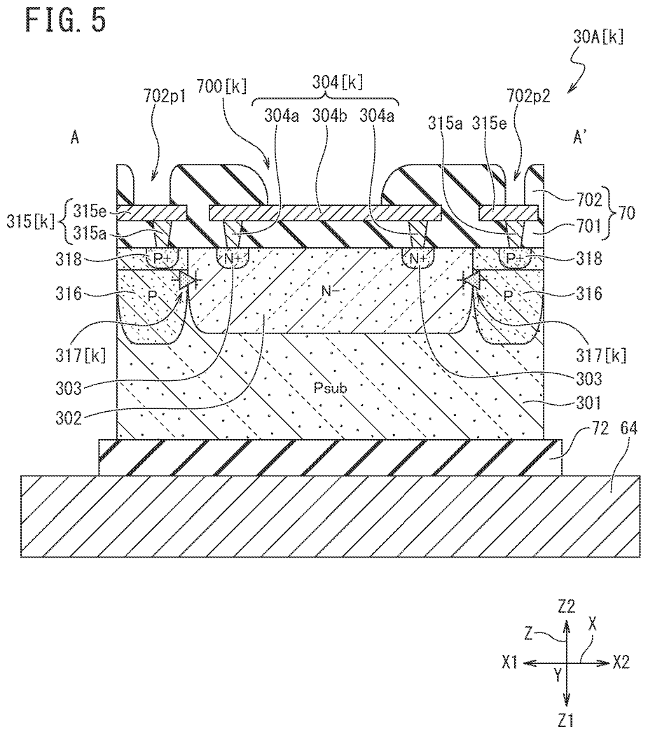

As exemplarily illustrated in FIG. 1, each of the semiconductor chips 30A[k] includes a corresponding one of diodes D[k] (for example, D[U], D[V], or D[W]). Each of the diodes D[k] is a bootstrap diode that constitutes a route to charge a corresponding one of the capacitance elements B[k] (a charge route α) in the bootstrap operation. Each of the diodes D[k] includes a semiconductor substrate 301 (not illustrated in FIG. 1, see FIG. 5) and an N⁻ diffusion layer 302 (not illustrated in FIG. 1, see FIG. 5) that are formed in a corresponding one of the semiconductor chips 30A[k]. Anodes 315[k] (see FIG. 5) are shared by the diodes D[k], and the anodes 315[k] are electrically connected to the connection terminal Tc_H and the voltage terminal Hc. A cathode 304[k] of each of the diodes D[k] is electrically connected to a corresponding one of the connection terminals Tbs[k] and a corresponding one of the power supply terminals Hb[k].

Each of the semiconductor chips 30A[k] has, on the cathode 304[k] side of the diode D[k] in the semiconductor chip 30A[k], a resistance component (drift resistance) of the N⁻ diffusion layer 302 that is formed by the N⁻ diffusion layer 302 forming the diode D[k] and is connected in series with the diode D[k]. In FIG. 1, to facilitate understanding, the resistance component (drift resistance) of the N⁻ diffusion layer 302 of each of the diodes D[k] is illustrated as a resistance element R[k] (for example, R[U], R[V], or R[W]) that is disposed between the diode D[k] and a corresponding one of the connection terminals Tbs[k] and a corresponding one of the power supply terminals Hb[k]. Each of the resistance elements R[k] limits current flowing through the paired diode D[k] in the bootstrap operation. Each of the resistance elements R[k] may be, instead of the resistance component of the N⁻ diffusion layer 302 of the paired diode D[k], an element that is formed of, for example, polysilicon and is connected in series with the diode D[k].

A detailed configuration of each of the semiconductor chips 30A[k] will be described later. As described above, the semiconductor device 100A includes the semiconductor chips 30A[k] each of which is used for the bootstrap operation to generate a corresponding one of the power supply voltages Vb[k] and the number of which is the same as the number of the power supply terminals Hb[k]. Each of the semiconductor chips 30A[k] includes a corresponding one of the diodes D[k].

For example, the semiconductor device 100A includes three power supply terminals Hb[U], Hb[V], and Hb[W] and three semiconductor chips 30A[U], 30A[V], and 30A[W] that are used for the bootstrap operation to generate the power supply voltages Vb[k]. The semiconductor chip 30A[U] includes the diode D[U]. The semiconductor chip 30A[V] includes the diode D[V]. The semiconductor chip 30A[W] includes the diode D[W].

In the configuration described above, controlling each of the drive chips 22[k] to the ON state while maintaining the paired drive chip 21[k] in the OFF state causes the bootstrap operation to be executed. Each of the drive chips 22[k] being controlled to the ON state causes a charge route α in FIG. 1 to be formed. Note that although, in FIG. 1, only a charge route α going through the diode D[V] disposed in the semiconductor chip 30A[V] is illustrated for descriptive purposes, charge routes a are also likewise formed with respect to the U-phase and the W-phase.

Each of the charge routes a is a current route that goes through the connection terminal Tc_H, a corresponding one of the diodes D[k], a corresponding one of the resistance elements R[k], a corresponding one of the connection terminals Tbs[k], a corresponding one of the capacitance elements B[k], a corresponding one of the connection terminals Ts[k], a corresponding one of the drive chips 22[k], and a corresponding one of the connection terminals Tn[k] in this order. Each of the capacitance elements B[k] is charged by one of the charge routes a. Specifically, voltage across each of the capacitance elements B[k] is maintained at the control voltage Vcc due to the charging via one of the charge routes a. Therefore, each of the power supply voltages Vb[k] supplied to a corresponding one of the power supply terminals Hb[k] is set to a voltage higher than the power supply voltage Vs[k] at a corresponding one of the power supply terminals Hs[k] by the control voltage Vcc. As described above, the bootstrap operation is an operation to generate each of the power supply voltages Vb[k], using a bootstrap circuit including a corresponding one of the semiconductor chips 30A[k] and a corresponding one of the capacitance elements B[k].

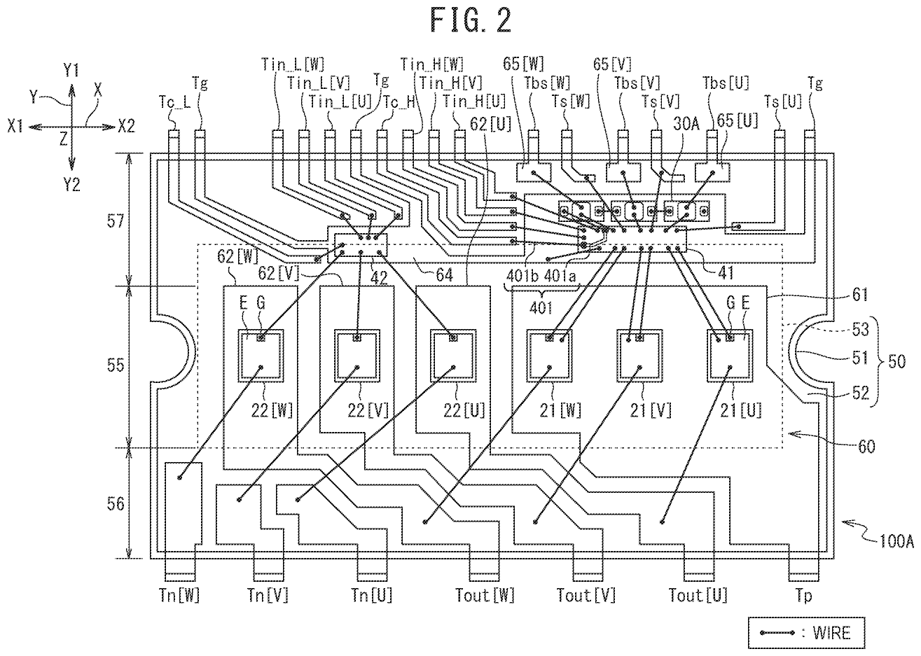

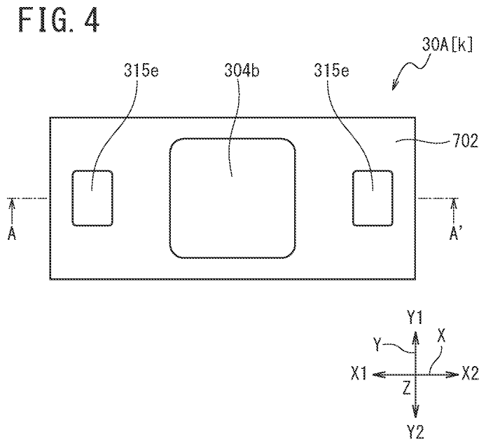

FIG. 2 is a layout diagram illustrative of an arrangement of various types of components included in the semiconductor device 100A according to the first embodiment. In FIG. 2, wires each of which connects predetermined elements to each other are illustrated by straight lines having black dots at both ends. FIG. 3 is a layout diagram illustrative of a vicinity of the semiconductor chips 30A[U], 30A[V], and 30A[W] and the high-potential-side control chip 41 included in the semiconductor device 100A in an enlarged manner. FIG. 4 is a plan view illustrative of a configuration example of one of the semiconductor chips 30A[k] included in the semiconductor device 100A. FIG. 5 is a cross-sectional view of the semiconductor chip 30A[k] taken along the line A-A′ illustrated in FIG. 4.

In the following description, as exemplarily illustrated in FIGS. 2 to 5, an X-axis, a Y-axis, and a Z-axis orthogonal to one another are assumed. It is assumed that the longitudinal direction of the semiconductor device 100A (i.e., the long-side direction of a casing 50 (details will be described later) containing respective elements, such as the semiconductor chips 30A[k] and the control chips 41 and 42, and having a thin plate-like rectangular parallelepiped shape) is the X-axis direction. It is also assumed that the lateral direction of the semiconductor device 100A (i.e., the short-side direction of the casing 50) is the Y-axis direction. It is also assumed that the thickness direction (i.e., a direction orthogonal to the long-side direction and the short-side direction of the casing 50) of the semiconductor device 100A is the Z-axis direction. One direction along the X-axis is referred to as an X1 direction, and an opposite direction to the X1 direction is referred to as an X2 direction. Further, one direction along the Y-axis is referred to as a Y1 direction, and an opposite direction to the Y1 direction is referred to as a Y2 direction. Likewise, one direction along the Z-axis is referred to as a Z1 direction, and an opposite direction to the Z1 direction is referred to as a Z2 direction. Further, visually recognizing an arbitrary element of the semiconductor device 100A in a Z-axis direction (the Z1 direction or the Z2 direction) is referred to as “viewed in plan” below.

Note that although when the semiconductor device 100A is actually used, the semiconductor device 100A can be installed in an arbitrary direction, it is assumed in the following description that the Z1 direction is the lower side and the Z2 direction is the upper side for descriptive purposes. Therefore, among arbitrary elements of the semiconductor device 100A, a surface facing the Z1 direction is sometimes referred to as “under surface”, and among the elements, a surface facing the Z2 direction is sometimes referred to as “upper surface”.

As exemplarily illustrated in FIG. 2, the semiconductor device 100A includes the casing 50 to house the respective elements exemplarily illustrated in FIG. 1. The casing 50 includes a resin case 51, a support plate 52, and a sealing resin 53. The resin case 51 is a rectangular frame-shaped structure formed of a resin material. The casing 50 is formed of one of various types of resin materials, such as polyphenylene sulfide (PPS) resin, polybutylene terephthalate (PBT) resin, poly butylene succinate (PBS) resin, polyamide (PA) resin, and acrylonitrile-butadiene-styrene (ABS) resin.

The support plate 52 is a plate-shaped member constituted by laminated layers including an insulating layer (not illustrated) that is formed of a resin material, such as epoxy resin, and a heat dissipation plate (not illustrated) that is formed of a high thermal conductive metallic material, such as aluminum and copper. The insulating layer covers the upper surface of the heat dissipation plate. The heat dissipation plate is a plate-shaped member. The support plate 52 is fixed to the resin case 51 in such a manner as to close an opening of the resin case 51. In a space surrounded by the resin case 51 with the support plate 52 used as a bottom surface, the three drive chips 21[k] (21[U], 21[V], and 21[W]), the three drive chips 22[k] (22[U], 22[V], and 22[W]), the three semiconductor chips 30A[k](30[U], 30[V], and 30[W]), the control chip 41, and the control chip 42 are housed. On the upper surface of each of the drive chips 21[k] and the drive chips 22[k], a main electrode E and a control electrode G are formed, and on the under surface of each of the drive chips 21[k] and the drive chips 22[k], a main electrode C (not illustrated in FIG. 2, see FIG. 1) is formed.

The sealing resin 53 is resin with which a space inside the resin case 51 is filled and seals elements housed in the space. The sealing resin 53 is formed of one of various types of resin materials, such as silicone gel and epoxy resin. Note that the sealing resin 53 may include, in addition to a resin material, one of various types of insulating fillers, such as silicon oxide and aluminum oxide.

In the casing 50, a lead frame 60 is installed. The lead frame 60 is wiring formed of a low-resistance metallic material, such as copper and copper alloy. The lead frame 60 is integrally formed with the resin case 51 by, for example, insert molding. The lead frame 60 is a conductor including a plurality of leads. The aforementioned connection terminals T are ends of the plurality of leads that are exposed to the outside out of the casing 50.

As exemplarily illustrated in FIG. 2, the casing 50 includes an element region 55, a terminal region 56, and a control region 57 as viewed in plan. Each of the element region 55, the terminal region 56, and the control region 57 is a region having a long length along the X-axis. The element region 55 is located between the terminal region 56 and the control region 57.

Some connection terminals T (Tin_H[k], Tin_L[k], Tc_H, Tc_L, Tg, and Tbs[k]) related to operation of the control chip 41 and the control chip 42 among the plurality of connection terminals T are control terminals projecting in the Y1 direction from a side surface of the control region 57 and are arranged along the X-axis at intervals to each other. Further, the connection terminals Ts[k] each of which is electrically connected to the main electrode E[k] of a corresponding one of the drive chips 21[k] and connected to the low potential side of a corresponding one of the capacitance elements B[k] and the connection terminal Tc_L that is connected to the voltage terminal Hc of the control chip 42 are also control terminals projecting in the Y1 direction from the side surface of the control region 57 and are arranged along the X-axis at intervals to each other. On the other hand, some connection terminals T (Tout[k], Tp, and Tn[k]) related to power supplied to the motor M among the plurality of connection terminals T are terminals projecting in the Y2 direction from a side surface of the terminal region 56 and are arranged along the X-axis at intervals to each other.

As exemplarily illustrated in FIG. 2, the lead frame 60 includes a die pad 61 and three die pads 62[k]. Each of the die pad 61 and the die pads 62[k] is a metal plate located in the element region 55 as viewed in plan. On the die pad 61, the three drive chips 21[k] are mounted. On each of the die pads 62[k], a corresponding one of the drive chips 22[k] is mounted. For the mounting of the drive chips 21[k] and the drive chips 22[k], a conductive bonding material, such as solder and metal sintered material, is used. As understood from the above description, the three drive chips 21[k] and the three drive chips 22[k] are installed in the element region 55. Note that the three die pads 62[k] may be replaced by a single die pad.

The lead frame 60 includes leads extending from respective ones of the connection terminal Tp, the connection terminals Tout[k], and the connection terminals Tn[k]. The connection terminal Tp is connected to the die pad 61 via a lead (not illustrated). Therefore, the main electrode C (not illustrated in FIG. 2, see FIG. 1) on the under surface of each of the drive chips 21[k] is electrically connected to the connection terminal Tp. Each of the connection terminals Tout[k] is connected to a corresponding one of the die pads 62[k] via a lead (not illustrated). Further, each of the connection terminals Tout[k] is electrically connected to the main electrode E on the upper surface of a corresponding one of the drive chips 21[k] by a wire. Therefore, as exemplarily illustrated in FIG. 1, the main electrode E of each of the drive chips 21[k] and the main electrode C on the under surface of the paired drive chip 22[k] are electrically connected to a corresponding one of the connection terminals Tout[k]. Further, each of the connection terminals Tn[k] is electrically connected to the main electrode E on the upper surface of a corresponding one of the drive chips 22[k] by a wire.

Further, as exemplarily illustrated in FIG. 2, the lead frame 60 includes a die pad 64 and three connection pads 65[k]. The die pad 64 and the connection pads 65[k] are metal plates located in the control region 57 as viewed in plan.

The lead frame 60 includes leads extending from connection terminals T for control (Tin_H[k], Tin_L[k], Tc_H, Tc_L, Tg, Tbs[k], and Ts[k]) related to operation of the control chip 41 and the control chip 42. The die pad 64 is connected to connection terminals Tg via leads Rdg. Therefore, to the die pad 64, the ground voltage (GND) is supplied from the connection terminals Tg. The ground voltage (GND) is an example of a “reference voltage”. Note that the die pad 64 and the connection terminals Tg may be integrally formed.

The control chip 41 is bonded to a front surface of the die pad 64. Although details will be described later, a conductive material (such as bonding material and solder) is used for mounting of the control chip 41. Therefore, the under surface of the control chip 41 and the die pad 64 are electrically connected to each other.

On the upper surface of the control chip 41, the aforementioned plurality of terminals H are formed (see FIG. 3). Each of the terminals H of the control chip 41 is electrically connected to one of the drive chips 21[k] or one of the connection terminals T by a wire. For example, as exemplarily illustrated in FIGS. 2 and 3, each of the output terminals Hout[k] of the control chip 41 is connected to the control electrode G on the upper surface of a corresponding one of the drive chips 21[k], and each of the middle terminals Hm[k] is connected to the main electrode E on the upper surface of a corresponding one of the drive chips 21[k]. Further, each of the power supply terminals Hs[k] on the upper surface of the control chip 41 is connected to a lead connected to a corresponding one of connection terminals Ts[k]. Each of the middle terminals Hm[k] and a corresponding one of the power supply terminals Hs[k] are electrically connected to each other inside the control chip 41. A ground terminal Hg disposed on a front surface of the control chip 41 is connected to the die pad 64 via a wire Qdg.

As exemplarily illustrated in FIG. 2, the control chip 42 is bonded to the front surface of the die pad 64. For mounting of the control chip 42, an insulating adhesive agent is used. Therefore, the under surface of the control chip 42 and the die pad 64 are electrically insulated from each other. On the upper surface of the control chip 42, the aforementioned plurality of terminals L (see FIG. 1) are formed. Each of the terminals L of the control chip 42 is electrically connected to one of the drive chips 22[k] or one of the connection terminals T by a wire. For example, each of the output terminals Lout[k] (see FIG. 1) of the control chip 42 is connected to the control electrode G on the upper surface of a corresponding one of the drive chips 22[k]. Further, the voltage terminal Lc (see FIG. 1) is connected to a lead connected to a connection terminal Tc_L, and the ground terminal Lg (see FIG. 1) is connected to leads connected to the connection terminals Tg.

Further, the lead frame 60 includes a lead Rd63 for supplying the control voltage Vcc to the voltage terminal Hc. The lead Rd63 is an example of a “first conductor”. The lead Rd63 is electrically connected to a connection terminal Tc_H (see FIG. 1) to which the control voltage Vcc is input from an external power supply 104 (see FIG. 1). The semiconductor device 100A includes a wiring member 401 electrically connected to the lead Rd63. The wiring member 401 is an example of a “second wiring”.

The wiring member 401 includes the relay pattern 401a and a wire 401b. The relay pattern 401a electrically connects a relay terminal Hr and the voltage terminal Hc to each other. The wire 401b electrically connects the voltage terminal Hc and the lead Rd63 to each other.

The voltage terminal Hc is electrically connected to the connection terminal Tc_H via the wire 401b and the lead Rd63. Therefore, to the voltage terminal Hc, the control voltage Vcc is supplied from the connection terminal Tc_H. The connection terminal Tc_H and the lead Rd63 may be integrally formed. Note that the lead Rd63 is an example of the “first conductor”. Therefore, the semiconductor device 100A includes the lead Rd63 (an example of the first conductor) for supplying the control voltage Vcc (an example of a predetermined control voltage) to the voltage terminal Hc (an example of the first terminal). A portion or all of the lead Rd63 and the connection terminal Tc_H may be defined as the “first conductor”.

Each of the connection pads 65[k] is connected to a corresponding one of the connection terminals Tbs[k] via a lead. The three connection pads 65[k] are arranged along the X-axis at intervals to each other. Specifically, the three connection pads 65[k] are arranged along a peripheral edge located on the Y1 direction side of the casing 50. As described before, to each of the connection terminals Tbs[k], the high potential side of a corresponding one of the capacitance elements B[k] is connected. That is, to each of the connection pads 65[k], a corresponding one of the capacitance elements B[k] is externally connected. Each of the connection pads 65[k], a corresponding one of the connection terminals Tbs[k], and a lead connecting the connection pad 65[k] and the connection terminal Tbs[k] may be integrally formed.

Next, a specific configuration of the semiconductor chips 30A[k] will be described using FIGS. 4 and 5 while referring to FIGS. 1 to 3. As exemplarily illustrated in FIG. 5, each of the semiconductor chips 30A[k] includes a corresponding one of the diodes D[k]. Each of the diodes D[k] includes a P-type (an example of a first conductivity type) diffusion layer 316 that is formed in a front surface layer of the P-type semiconductor substrate 301 and an N-type (an example of a second conductivity type) N⁻ diffusion layer 302 that is formed in the front surface layer of the semiconductor substrate 301. The P-type diffusion layer 316 is an example of a “first semiconductor layer”. The N⁻ diffusion layer 302 is an example of a “second semiconductor layer”.

Note that the front surface layer of the semiconductor substrate 301 means a layer that includes the front surface of the semiconductor substrate 301 and a region located in a vicinity of the front surface of the semiconductor substrate 301 in a depth direction (for example, the Z1 direction) orthogonal to the front surface of the semiconductor substrate 301. The P-type diffusion layer 316 is formed in an area on the front surface layer of the semiconductor substrate 301 in which the N⁻ diffusion layer 302 is not formed. In FIG. 5, to facilitate understanding, a pn junction portion 317[k] that is formed at a junction portion between the N⁻ diffusion layer 302 and the P-type diffusion layer 316 is illustrated by schematic symbols of diodes.

The P-type diffusion layer 316 forms an anode region of the diode D[k], and the N⁻ diffusion layer 302 forms a cathode region of the diode D[k]. Note that the N⁻ diffusion layer 302 also serves as a corresponding one of the resistance elements R[k]. Although the semiconductor substrate 301 also functions as an anode region of the diode D[k], a portion through which current mainly flows is the junction portion between the N⁻ diffusion layer 302 and the diffusion layer 316.

The pn junction portion 317[k] of each of the diodes D[k] is formed at a junction portion between the diffusion layer 316 and the N⁻ diffusion layer 302.

As exemplarily illustrated in FIG. 5, each of the semiconductor chips 30A[k] includes the P-type diffusion layer 316 that is formed in an area in the front surface layer of the semiconductor substrate 301 in which the N⁻ diffusion layer 302 is not formed. Therefore, the N⁻ diffusion layer 302 is formed in an island shape as viewed in plan, and the diffusion layer 316 is formed in the surroundings of the N⁻ diffusion layer 302. Although, in FIG. 5, portions of the diffusion layer 316 at both ends and portions of the diffusion layer 316 on both sides of the N⁻ diffusion layer 302 are formed with different widths, the portions may be formed with the same width.

The diffusion layer 316 is formed by ion-implanting, for example, boron as a P-type impurity in a predetermined region on the front surface of the semiconductor substrate 301 and activating a site at which the P-type impurities are ion-implanted. The diffusion layer 316 is, for example, formed with a depth deeper than depth of the N⁻ diffusion layer 302.

Each of the semiconductor chip 30A[k] includes P⁺ diffusion layers 318 that are formed in portions of a front surface of the diffusion layer 316. The P⁺ diffusion layers 318, for example, have a higher impurity concentration than the diffusion layer 316. The concentration of the P-type impurities in the P⁺ diffusion layers 318 is the same as, for example, concentration of N-type impurities in N⁺ diffusion layers 303.

The P⁺ diffusion layers 318 are formed with depths shallower than a depth of the diffusion layer 316 in predetermined regions on the front surface of the diffusion layer 316 by ion-implanting, for example, boron as a P-type impurity and activating sites at which the P-type impurities are ion-implanted.

Each of the P⁺ diffusion layers 318 formed in a region that is a portion of the front surface of the P-type diffusion layer 316 and is located between a sidewall of the semiconductor substrate 301 and the N⁻ diffusion layer 302. Between each of the P diffusion layers 318 and the N⁻ diffusion layer 302, the P-type diffusion layer 316 is interposed. Further, between the P-type diffusion layer 316 and each of the N⁺ diffusion layers 303, the N⁻ diffusion layer 302 is interposed. For example, in the front surface and a vicinity of the front surface (i.e., the front surface layer) of the semiconductor substrate 301, the P⁺ diffusion layer 318, the P-type diffusion layer 316, the N⁻ diffusion layer 302, and the N⁺ diffusion layer 303 are arranged side by side in this order in a direction parallel with the front surface.

As exemplarily illustrated in FIGS. 4 and 5, each of the semiconductor chips 30A[k] includes a corresponding one of the cathodes 304[k] that is formed on the N⁻ diffusion layer 302 in the semiconductor chip 30A[k]. The cathode 304[k] is formed in contact with the NW diffusion layers 303. Each of the cathodes 304[k] is electrically connected to a corresponding one of the power supply terminals Hb[k] via a corresponding one of wires Qb[k] (an example of first wirings) (not illustrated in FIGS. 4 and 5, see FIG. 3).

As exemplarily illustrated in FIG. 5, each of the cathodes 304[k] is formed with conductive plugs 304a in contact with the N⁺ diffusion layers 303 of a corresponding one of the semiconductor chips 30A[k]. Thus, each of the cathodes 304[k] and the N⁺ diffusion layers 303 of a corresponding one of the semiconductor chips 30A[k] are in ohmic contact. This configuration enables reduction in contact resistance between each of the cathodes 304[k] and the NW diffusion layers 303 of a corresponding one of the semiconductor chips 30A[k] to be achieved.

Each of the semiconductor chips 30A[k] includes a corresponding one of anodes 315[k]. The anode 315[k] is formed on the diffusion layer 316 and is electrically connected to the lead Rd63 (not illustrated in FIGS. 4 and 5, see FIG. 3) via the wiring member 401 (not illustrated in FIGS. 4 and 5, see FIG. 3).

More specifically, each of the anodes 315[k] includes conductive plugs 315a each of which is formed in contact with one of the P⁺ diffusion layer 318 and an electrode plate 315e that is formed in contact with the conductive plugs 315a. Each of the conductive plugs 315a is formed in contact with one of the P⁺ diffusion layers 318. Thus, the anode 315[k] and the P⁺ diffusion layers 318 are ohmic-connected. This configuration enables reduction in contact resistance between the anode 315[k] and the P⁺ diffusion layers 318 to be achieved.

The electrode plate 315e has a thin plate-like rectangular parallelepiped shape. The electrode plate 315e has an opening into which the electrode pad 304b of the cathode 304[k] is inserted at a location at which the cathode 304[k] is arranged. The electrode pad 304b of the cathode 304[k] is arranged in the opening without contact with the electrode plate 315e. The electrode plate 315e is formed of, for example, aluminum.

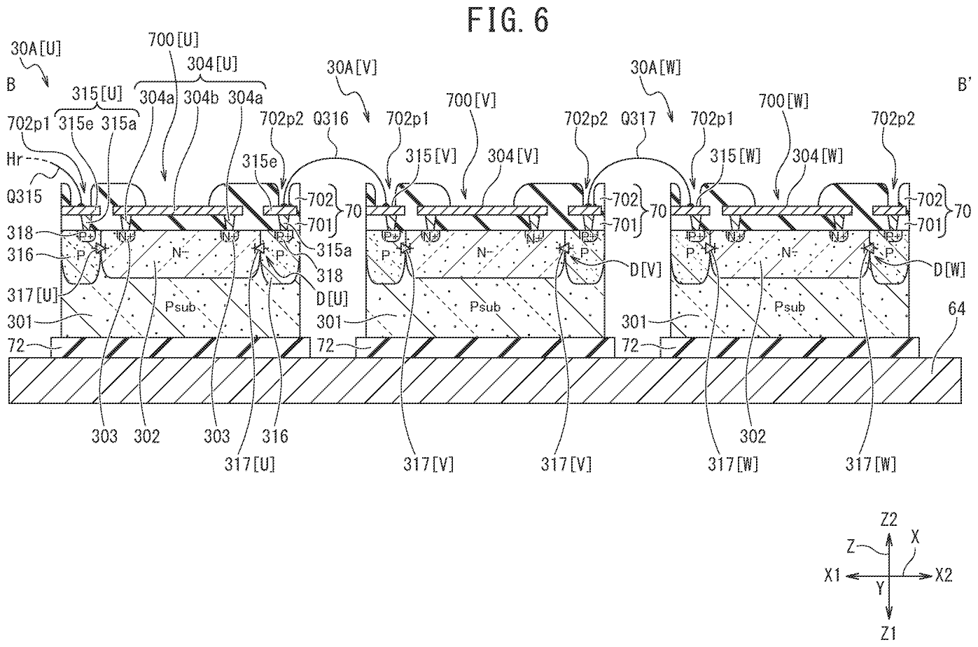

As exemplarily illustrated in FIG. 3, the electrode plate 315e that is a portion of the anode 315[k] of each of the semiconductor chips 30A[k] (for example, the semiconductor chip 30A[U] illustrated in FIG. 6, which will be described later) is electrically connected to the relay terminal Hr of the control chip 41 by a wire Q315. The wire Q315 is a linear conductor that is formed by wire bonding.

As exemplarily illustrated in FIGS. 4 and 5, each of the semiconductor chips 30A[k] includes an insulating film 70 that is formed covering the front surface of the semiconductor substrate 301. The insulating film 70 includes an insulating film 701, such as an oxide film, that is formed in contact with the front surface of the semiconductor substrate 301 and a protective film 702, such as polyimide, that is formed on the insulating film 701. Further, each of the semiconductor chips 30A[k] has openings 702p1, 702p2, and 700[k] (not illustrated in FIG. 3, see FIG. 5) that are formed in the insulating film 70 (not illustrated in FIG. 3, see FIGS. 4 and 5). On the bottom surfaces of the openings 702p1 and 702p2, portions of a front surface of the electrode plate 315e are exposed. On the bottom surface of the opening 700[k], a portion of a front surface of the electrode pad 304b is exposed.

In one of the semiconductor chips 30A[k] (for example, the semiconductor chip 30A[U] illustrated in FIG. 6, which will be described later), one end of the wire Q315 is bonded to a portion of the front surface of the electrode plate 315e that is exposed in the opening 702p1 formed in the insulating film 70. The other end of the wire Q315 is bonded to a front surface of the relay terminal Hr. The relay terminal Hr is formed at one end of the relay pattern 401a. At the other end of the relay pattern 401a, the voltage terminal He is formed. The voltage terminal Hc and the lead Rd63 are connected to each other by the wire 401b. The wire 401b is a linear conductor that is formed by wire bonding.

The lead Rd63 is connected to the connection terminal Tc_H (see FIGS. 1 and 2) to which the control voltage Vcc is input from the external power supply 104 (see FIG. 1). Thus, to the anodes 315[k], the control voltage Vcc is supplied via the connection terminal Tc_H, the lead Rd63, the wiring member 401 (i.e., the wire 401b and the relay pattern 401a), and the wire Q315.

Returning to FIG. 5, each of the semiconductor chips 30A[k] has a surface on the opposite side to the front surface of the semiconductor substrate 301 (i.e., the back surface) adhered to the die pad 64 by an insulating adhesive agent 72. Although details will be described later, to a body of the semiconductor substrate 301 of each of the semiconductor chips 30A[k], the control voltage Vcc is supplied from the anode 315[k] of the semiconductor chip 30A[k]. On the other hand, the die pad 64 is connected to connection terminals Tg to which a ground voltage is supplied via leads Rdg. Thus, to the die pad 64, the ground voltage is supplied via the connection terminals Tg and the leads Rdg.

Therefore, voltage supplied to the semiconductor substrates 301 of the semiconductor chips 30A[k] and voltage supplied to the die pad 64 are different from each other. However, since the semiconductor substrate 301 of each of the semiconductor chips 30A[k] and the die pad 64 are insulated from each other by the insulating adhesive agent 72, the connection terminal Tc_H and the connection terminals Tg are prevented from being short-circuited.

A ground terminal Hg disposed on the control chip 41 is connected to the die pad 64 via a wire Qgd. The wire Qgd is a linear conductor that is formed by wire bonding. One end of the wire Qgd is bonded to a front surface of the ground terminal Hg of the control chip 41, and the other end of the wire Qgd is bonded to the front surface of the die pad 64. Because of this configuration, to the ground terminal Hg of the control chip 41, the ground voltage is supplied via the connection terminals Tg, the die pad 64, and the wire Qgd.

FIG. 6 is a cross-sectional view illustrative of an arrangement of and connections among the plurality of (three in the present embodiment) semiconductor chips 30A[k] included in the semiconductor device 100A. FIG. 6 is a cross-sectional view illustrative of the three semiconductor chips 30A[U], 30A[V], and 30A[W] taken along the line B-B′ illustrated in FIG. 3.

As exemplarily illustrated in FIG. 6, the semiconductor device 100A includes, for example, the three semiconductor chips 30A[U], 30A[V], and 30A[W]. The semiconductor chips 30A[U], 30A[V], and 30A[W] are arranged at a constant interval to each other. For example, the semiconductor chips 30A[U], 30A[V], and 30A[W] are arranged at a constant interval to each other along the longitudinal direction (the X-axis direction) of the control chip 41. Each of the semiconductor chips 30A[U], 30A[V], and 30A[W] is fixed to the front surface of the die pad 64 via the insulating adhesive agent 72.

Each of the semiconductor chips 30A[U], 30A[V], and 30A[W] has the openings 702p1 and 702p2 that are formed in the insulating film 70. For example, to the front surface of the electrode plate 315e that is exposed on the bottom surface of the opening 702p1 of the semiconductor chip 30A[U], one end of the wire Q315 is bonded. The other end of the wire Q315 is bonded to the front surface of the relay terminal Hr.

To the front surface of the electrode plate 315e that is exposed on the bottom surface of the opening 702p2 of the semiconductor chip 30A[U], one end of a wire Q316 is bonded. The other end of the wire Q316 is bonded to the front surface of the electrode plate 315e that is exposed on the bottom surface of the opening 702p1 of the semiconductor chip 30A[V]. The wire Q316 is a linear conductor that is formed by wire bonding. Because of this configuration, the electrode plate 315e of the semiconductor chip 30A[U] and the electrode plate 315e of the semiconductor chip 30A[V] are electrically connected to each other via the wire Q316. To the electrode plate 315e of the semiconductor chip 30A[V], the control voltage Vcc is supplied via the wires Q315 and Q316.

To the front surface of the electrode plate 315e that is exposed on the bottom surface of the opening 702p2 of the semiconductor chip 30A[V], one end of a wire Q317 is bonded. The other end of the wire Q317 is bonded to the front surface of the electrode plate 315e that is exposed on the bottom surface of the opening 702p1 of the semiconductor chip 30A[W]. The wire Q317 is a linear conductor that is formed by wire bonding. Because of this configuration, the electrode plate 315e of the semiconductor chip 30A[V] and the electrode plate 315e of the semiconductor chip 30A[W] are electrically connected to each other via the wire Q317. To the electrode plate 315e of the semiconductor chip 30A[W], the control voltage Vcc is supplied via the wires Q315, Q316, and Q317.

Note that in FIG. 6, the semiconductor chip 30A[U] is an example of a “first semiconductor chip” and the diode D[U] that the semiconductor chip 30A[U] includes is an example of a “first diode”. The diode D[U] is used for bootstrap operation to generate the power supply voltage Vb[U] (an example of a first AC phase of power supply voltage). The semiconductor chip 30A[V] is an example of a “second semiconductor chip” and the diode D[V] that the semiconductor chip 30A[V] includes is an example of a “second diode”. The diode D[V] is used for bootstrap operation to generate the power supply voltage Vb[V] (an example of a second AC phase of the power supply voltage). The semiconductor chip 30A[W] is an example of a “third semiconductor chip” and the diode D[W] that the semiconductor chip 30A[W] includes is an example of a “third diode”. The diode D[W] is used for bootstrap operation to generate the power supply voltage Vb[W] (an example of a third AC phase of the power supply voltage). Further, the wire Q315 is an example of the “second wiring”. The wires Q316 and Q317 are examples of a “third wiring”. The wire Q316 is an example of a “first wire” in the third wiring. The wire Q317 is an example of a “second wire” in the third wiring.

Next, connections between the cathodes 304[k] of the semiconductor chips 30A[k] and the wires Qb[k] will be more specifically described. As exemplarily illustrated in FIG. 3, to the electrode pad 304b of each of the cathodes 304[k], a corresponding one of the wires Qb[k] is connected. Each of the wires Qb[k] is a linear conductor that is formed by wire bonding. Each of the wires Qb[k] includes a wire wiring Qb1 and a wire wiring Qb2.

The wire wiring Qb1 of the wire Qb[U] is a wiring that connects the connection terminal Tbs[U] and the cathode 304[U] of the semiconductor chip 30A[U]. Specifically, one end of the wire wiring Qb1 of the wire Qb[U] is bonded to a front surface of the connection pad 65[U]. The other end of the wire wiring Qb1 of the wire Qb[U] is bonded to a front surface of the electrode pad 304b of the cathode 304[U], which is exposed in the opening 700[U]. Because of this configuration, the connection terminal Tbs[U] and the cathode 304[U] of the semiconductor chip 30A[U] are electrically connected via the connection pad 65[U] and the wire wiring Qb1 of the wire Qb[U].

The wire wiring Qb2 of the wire Qb[U] is a wiring that connects the cathode 304[U] of the semiconductor chip 30A[U] and the power supply terminal Hb[U] of the control chip 41. Specifically, one end of the wire wiring Qb2 of the wire Qb[U] is bonded to the front surface of the electrode pad 304b of the cathode 304[U], which is exposed in the opening 700[U]. The other end of the wire wiring Qb2 of the wire Qb[U] is bonded to a front surface of the power supply terminal Hb[U] of the control chip 41. Because of this configuration, the cathode 304[U] of the semiconductor chip 30A[U] and the power supply terminal Hb[U] of the control chip 41 are electrically connected via the wire wiring Qb2 of the wire Qb[U].

The wire wiring Qb1 of the wire Qb[V] is a wiring that connects the connection terminal Tbs[V] and the cathode 304[V] of the semiconductor chip 30A[V]. Specifically, one end of the wire wiring Qb1 of the wire Qb[V] is bonded to a front surface of the connection pad 65[V]. The other end of the wire wiring Qb1 of the wire Qb[V] is bonded to a front surface of the electrode pad 304b of the cathode 304[V], which is exposed in the opening 700[V]. Because of this configuration, the connection terminal Tbs[V] and the cathode 304[V] of the semiconductor chip 30A[V] are electrically connected via the connection pad 65[V] and the wire wiring Qb1 of the wire Qb[V].

The wire wiring Qb2 of the wire Qb[V] is a wiring that connects the cathode 304 [V] of the semiconductor chip 30A[V] and the power supply terminal Hb[V] of the control chip 41. Specifically, one end of the wire wiring Qb2 of the wire Qb[V] is bonded to the front surface of the electrode pad 304b of the cathode 304[V], which is exposed in the opening 700[V]. The other end of the wire wiring Qb2 of the wire Qb[V] is bonded to a front surface of the power supply terminal Hb[V] of the control chip 41. Because of this configuration, the cathode 304[V] of the semiconductor chip 30A[V] and the power supply terminal Hb[V] of the control chip 41 are electrically connected via the wire wiring Qb2 of the wire Qb[V].

The wire wiring Qb1 of the wire Qb[W] is a wiring that connects the connection terminal Tbs[W] and the cathode 304[W] of the semiconductor chip 30A[W]. Specifically, one end of the wire wiring Qb1 of the wire Qb[W] is bonded to a front surface of the connection pad 65[W]. The other end of the wire wiring Qb1 of the wire Qb[W] is bonded to a front surface of the electrode pad 304b of the cathode 304[W], which is exposed in the opening 700[W]. Because of this configuration, the connection terminal Tbs[W] and the cathode 304[W] of the semiconductor chip 30A[W] are electrically connected via the connection pad 65[W] and the wire wiring Qb1 of the wire Qb[W].

The wire wiring Qb2 of the wire Qb[W] is a wiring that connects the cathode 304[W] of the semiconductor chip 30A[W] and the power supply terminal Hb[W] of the control chip 41. Specifically, one end of the wire wiring Qb2 of the wire Qb[W] is bonded to the front surface of the electrode pad 304b of the cathode 304[W], which is exposed in the opening 700[W]. The other end of the wire wiring Qb2 of the wire Qb[W] is bonded to a front surface of the power supply terminal Hb[W] of the control chip 41. Because of this configuration, the cathode 304[W] of the semiconductor chip 30A[W] and the power supply terminal Hb[W] of the control chip 41 are electrically connected via the wire wiring Qb2 of the wire Qb[W].

As described above, the semiconductor device 100A includes the wires Qb[k] (an example of the plurality of first wirings) that are individually connected to the power supply terminals Hb[k] (an example of the plurality of second terminals) and are for supplying the control voltage Vcc to the plurality of power supply terminals Hb[k].

As exemplarily illustrated in FIG. 3, the semiconductor device 100A includes wires Qu, Qv, and Qw that connect input terminals Hin[U], Hin[V], and Hin[W] disposed on the control chip 41 and leads Rd[U], Rd[V], and Rd[W] connected to connection terminal Tin_H[U], Tin_H[V], and Tin_H[W], respectively. The wires Qu, Qv, and Qw are linear conductors that are formed by wire bonding.

The semiconductor device 100A includes the wire Qdg that connects the ground terminal Hg disposed on the control chip 41 and a lead Rdg connected to the die pad 64. The wire Qdg is a linear conductor that is formed by wire bonding. Thus, to the ground terminal Hg of the control chip 41, the ground voltage applied to the die pad 64 is supplied. Because of this configuration, the ground voltages of the control chip 41 and the control chip 42 become the same potential as each other.

The semiconductor device 100A includes wires Qg[U], Qg[V], and Qg[W] that connect the output terminals Hout[U], Hout[V], and Hout[W] disposed on the control chip 41 and the control electrodes G of the drive chips 21[k], respectively. The wires Qg[U], Qg[V], and Qg[W] are linear conductors that are formed by wire bonding.

The semiconductor device 100A includes wires Qe[U], Qe[V], and Qe[W] that connect the middle terminals Hm[U], Hm[V], and Hm[W] disposed on the control chip 41 and the main electrodes E of the drive chips 21[k], respectively. The wires Qe[U], Qe[V], and Qe[W] are linear conductors that are formed by wire bonding.

The semiconductor device 100A includes wires Qs[U], Qs[V], and Qs[W] that connect the power supply terminals Hs[U], Hs[V], and Hs[W] disposed on the control chip 41 and leads Rds[U], Rds[V], and Rds[W] connected to the connection terminal Ts[U], Ts[V], and Ts[W], respectively. The wires Qs[U], Qs[V], and Qs[W] are linear conductors that are formed by wire bonding.

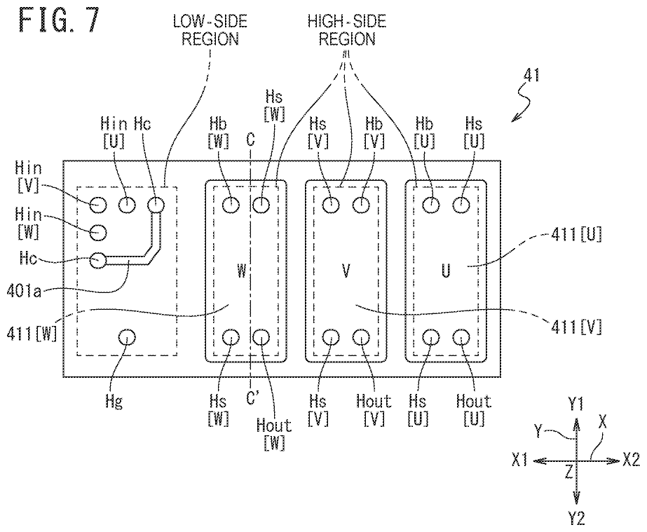

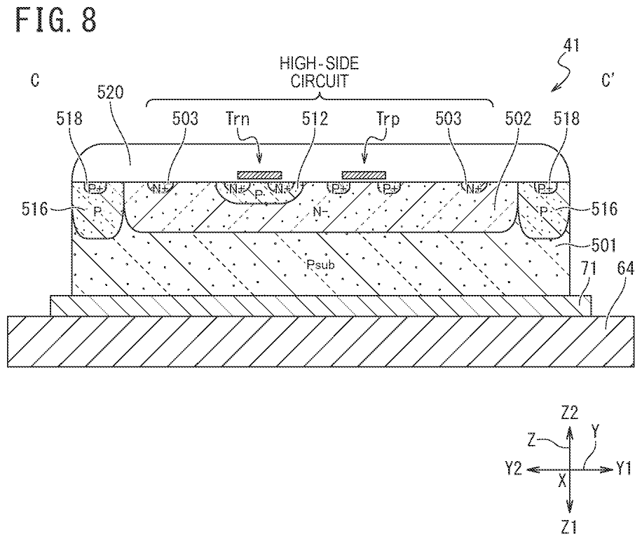

FIG. 7 is a plan view illustrative of a configuration of the high-potential-side control chip 41 included in the semiconductor device 100A. FIG. 8 is a cross-sectional view illustrative of the configuration of the control chip 41 included in the semiconductor device 100A according to the first embodiment of the present disclosure. FIG. 8 is a cross-sectional view of the high-potential-side control chip 41 taken along the line C-C′ illustrated in FIG. 7.

The control chip 41 exemplarily illustrated in FIG. 7 is an HVIC configured to control each of the high-potential-side drive chips 21[k]. The control chip 41 includes, for example, high-side regions to each of which one of the power supply voltages Vb[k] is supplied from the external power supply 103 and a low-side region to which the control voltage Vcc is supplied from the external power supply 104. The power supply voltages Vb[k] are higher voltages than the control voltage Vcc. The high-side regions include a control region 411[U] for controlling the drive chip 21[U], a control region 411[V] for controlling the drive chip 21[V], and a control region 411[W] for controlling the drive chip 21[W].

In the control region 411[U], one power supply terminal Hb[U], two power supply terminals Hs[U], and one output terminal Hout[U] are arranged. In the control region 411[V], one power supply terminal Hb[V], two power supply terminals Hs[V], and one output terminal Hout[V] are arranged. In the control region 411[W], one power supply terminal Hb[W], two power supply terminals Hs[W], and one output terminal Hout[W] are arranged. In the high-side regions, adjacent control regions among the control regions 411[U], 411[V], and 411[W] are electrically isolated from each other by depletion layers (withstand voltage regions) each of which is, for example, formed between a P⁺ diffusion layer 518 and an N⁺ diffusion layer 503 (not illustrated in FIG. 7, see FIG. 8), which will be described later. Alternatively, in the high-side regions, adjacent control regions among the control regions 411[U], 411[V], and 411[W] may be electrically isolated by element isolation portions, such as a local oxidation of silicon (LOCOS) and a trench isolation.

In the low-side region, the input terminals Hin[U], Hin[V], and Hin[W], the ground terminal Hg, the voltage terminal Hc, the relay terminal Hr, and the relay pattern 401a that electrically connects the voltage terminal Hc and the relay terminal Hr are arranged. The low-side region and the high-side regions are electrically isolated from each other by a depletion layer (a withstand voltage region) that is formed between a P⁺ diffusion layer 518 and an N⁺ diffusion layer 503 (not illustrated in FIG. 7, see FIG. 8), which will be described later. Alternatively, the low-side region and the high-side regions may be isolated electrically by an element isolation portion, such as a LOCOS and a trench isolation.

As exemplarily illustrated in FIG. 8, the control chip 41 includes a P-type semiconductor substrate 501, the high-side regions that are formed on the P-type semiconductor substrate 501, and the low-side region (not illustrated in FIG. 8, see FIG. 7) formed on the P-type semiconductor substrate 501. Further, the control chip 41 includes N-type N⁻ well layers 502 that are formed in a front surface layer of the P-type semiconductor substrate 501, P-type P well layers 516 that are formed in areas in the front surface layer of the P-type semiconductor substrate 501 in which the N⁻ well layers 502 are not formed, and P-type P⁺ diffusion layers 518 that are formed in front surface layers of the P-type P well layers 516. The P well layers 516 have a higher P-type impurity concentration than the P-type semiconductor substrate 501. The P⁺ diffusion layers 518 have a higher P-type impurity concentration than the P well layers 516. Although not illustrated, the P⁺ diffusion layers 518 extend in a direction orthogonal to the plane of paper of FIG. 8 (the X-axis direction) and are electrically connected to an arbitrary terminal (for example, the ground terminal Hg). Because of this configuration, an arbitrary voltage (for example, the ground voltage) is supplied to the P diffusion layers 518, the P well layers 516, and the P-type semiconductor substrate 501.

Further, as exemplarily illustrated in FIG. 8, an N-type N⁺ diffusion layer 503 and a P well layer 512 are formed in each of the N⁻ well layers 502. The N⁺ diffusion layer 503 has a higher N-type impurity concentration than the N⁻ well layer 502. Although not illustrated, the N⁺ diffusion layer 503 extends in a direction orthogonal to the plane of paper of FIG. 8 (for example, the X-axis direction) and is electrically connected to an arbitrary terminal (for example, one of the power supply terminals Hb[k]). Because of this configuration, an arbitrary voltage (for example, one of the power supply voltages Vb[k], that is, a high potential of one of the capacitance elements B[k] illustrated in FIG. 1) is supplied to the N⁺ diffusion layer 503.

For example, in each of the N⁻ well layers 502, a P-type MOS transistor Trp is formed. In each of the P well layers 512, an N-type MOS transistor Trn is formed. A portion of each of the high-side regions is formed by a CMOS transistor including MOS transistors Trp and Trn. Each of the CMOS transistors is, for example, a buffer circuit configured to output a signal to be input to the control electrode G of one of the drive chips 21[k] (not illustrated in FIG. 8, see FIG. 1).

Each of the P well layers 512 extends in a direction orthogonal to the plane of paper of FIG. 8 (for example, the X-axis direction) and is electrically connected to an arbitrary terminal (for example, one of the power supply terminals Hs[k]). Because of this configuration, an arbitrary voltage (for example, one of the power supply voltages Vs[k], that is, a low potential of one of the capacitance elements B[k] illustrated in FIG. 1) is supplied to one of the P well layers 512.

Note that a circuit formed in each of the high-side regions is not limited to the above-described buffer circuit and an arbitrary circuit, such as a current detection circuit and a latch circuit, may be formed.

On a front surface of the semiconductor substrate 501, an insulating film 520 is formed. The insulating film 520 can be configured to have a stacked structure of an insulating film, such as an oxide film, and a protective film, such as polyimide, in a similar manner to the insulating film 70.

Note that two regions, namely the N⁻ diffusion layer 302 and the diffusion layer 316, of each of the semiconductor chips 30A[k] are main regions that constitute the element. This is because the breakdown voltage of the element is determined by the two regions. Two regions, namely the N⁻ well layer 502 and the P well layer 516, of the control chip 41 and two regions, namely the N⁻ diffusion layer 302 and the diffusion layer 316, of each of the semiconductor chips 30A[k] can be formed by the same production method, respectively. Therefore, the aforementioned two regions of the control chip 41 and the aforementioned two regions of each of the semiconductor chips 30A[k] can be formed with the same depth and the same impurity concentration, respectively. Forming the major components of each of the semiconductor chips 30A[k] with the same depth and the same impurity concentration as those of the control chip 41 as described above enables each of the semiconductor chips 30A[k] to be easily designed based on the design of the control chip 41.

Although herein forming regions with the same depth and the same impurity concentration with respect to the above-described two regions was described, other regions, for example, the N⁺ diffusion layer 503 and the N⁺ diffusion layer 303, may be produced by the same production method.

Next, outlines of advantageous effects resulting from the configuration of the semiconductor device 100A will be described referring to FIGS. 1 to 8.

As exemplarily illustrated in FIGS. 1 to 8, the semiconductor device 100A is an intelligent power module (IPM) that is used as a three-phase inverter circuit configured to drive a motor M, such as a three-phase motor. In order to reduce mounting area in the IPM, the control chip 41, which is an HVIC, and the semiconductor chips 30A[k] each of which includes a corresponding one of the diodes D[k], which is a bootstrap diode (BSD), are arranged on the same die pad 64.

To the die pad 64, for example, the ground voltage is supplied. By arranging the anode 315[k] and the cathode 304[k], which are electrically connected to the diode D[k], on the front surface side of each of the semiconductor chips 30A[k] and arranging the insulating adhesive agent 72 on the back surface side of the semiconductor chip 30A[k], the diode D[k] is insulated from the die pad 64. The insulating adhesive agent 72 is an example of an “insulating material”.

The control chip 41 is fixed to the die pad 64 by a conductive adhesive agent 71. The conductive adhesive agent 71 is an example of a “conductive material”. By arranging the conductive adhesive agent 71 on the back surface side of the control chip 41, the ground voltage (GND) is supplied to the semiconductor substrate 501 included in the control chip 41. Because of this configuration, it is possible to, while avoiding reduction in noise resistance or insulation breakdown on the control chip 41 side, mount the control chip 41 and a plurality of (for example, three) semiconductor chips 30A[k] on the same die pad 64.

The advantageous effects resulting from the configuration of the semiconductor device 100A will be described in more detail, referring to FIGS. 1 to 8. In the semiconductor device 100A, one control chip 41, which is an HVIC, one semiconductor chip 30A[U] including the diode D[U], which is a BSD for the U-phase, one semiconductor chip 30A[V] including the diode D[V], which is a BSD for the V-phase, and one semiconductor chip 30A[W] including the diode D[W], which is a BSD for the W-phase, are arranged on the same die pad 64. To the die pad 64, for example, the ground voltage (GND) is supplied. Further, in the semiconductor chips 30A[U], 30A[V], and 30A[W], the high breakdown voltage diodes D[U], D[V], and D[W] are formed, respectively, each by a pn junction between an N⁻ diffusion layer 302 and a P-type diffusion layer 316.

In each of the semiconductor chips 30A[k], on the front surface of the N⁻ diffusion layer 302, which serves as a cathode, the N⁻ diffusion layers 303 that become ohmic are formed. On the front surface of the P-type diffusion layer 316, which serves as an anode, the P⁺ diffusion layers 318 that become ohmic are formed. On the N⁺ diffusion layers 303 and the P⁺ diffusion layers 318, the cathode 304[k] and the anode 315[k], which are made of aluminum or the like, are connected, respectively. On the front surface of the semiconductor substrate 301, the insulating film 70 is formed. In the insulating film 70, the opening 700[k] and the openings 702p1 and 702p2 are formed in such a way that one ends of wires can be bonded to the cathode 304[k] and the anode 315[k], respectively.

A charging current route of each of the diodes D[k] passes from the anode to the cathode on the front surface of a corresponding one of the semiconductor chips 30A[k] in a direction parallel or substantially parallel with the front surface of the semiconductor substrate 301 (i.e., a lateral direction). Adjusting impurity concentration and drift length of the N⁻ diffusion layer 302 of each of the semiconductor chips 30A[k] according to the required rated or guaranteed breakdown voltage of the IPM enables the semiconductor chip 30A[k] to cope with various breakdown voltage classes, such as 600 V and 1200 V.

Note that since dV/dt noise caused by switching of the power device or an external surge is input to not only the power supply terminal Hs[k] to which the anode 315[k] is electrically connected but also the power supply terminal Hb[k] to which the cathode 304[k] is electrically connected, dV/dt is also applied to each of the semiconductor chips 30A[k].

However, since each of the semiconductor chips 30A[k] does not have a high-side region compared with the control chip 41, junction area between the P-type semiconductor substrate 301 and the N⁻ diffusion layer 302 is small. Therefore, the amount of displacement current calculated as a product of junction capacitance Cb of each of the diodes D[k] and dV/dt is smaller than the amount of displacement current calculated as a product of junction capacitance Ch of the control chip 41 and dV/dt. Therefore, even when the back surface of each of the semiconductor chips 30A[k] including a corresponding one of the diodes D[k] is insulated, a rise of back surface potential is lower than a case where the back surface of the control chip 41 is insulated. When insulating adhesive agents of the same thickness are applied to the back surfaces of the semiconductor chips 30A[k] and the back surface of the control chip 41, a risk of insulation breakdown of the back surfaces of the semiconductor chips 30A[k] is lower than a risk of insulation breakdown of the back surface of the control chip 41.

When the control chip 41 and the semiconductor chips 30A[k] are arranged on the same die pad in order to reduce mounting area, arranging the anode electrodes and the cathode electrodes of the BSDs formed on the P-type semiconductor substrates (Psubs) on the front surface side and insulating the back surface side of the Psubs enable potentials of the die pad and the back surface of the HVIC to be fixed to GND. Because of this configuration, it is possible to, on the back surface side of the HVIC to which an inexpensive isolation method, such as a self-isolation method and a junction isolation method, is applied, extract carriers generated by switching noise or external noise and thereby prevent noise resistance from deteriorating. Further, in each of the semiconductor chips 30A[k], influence of a rise in Psub potential (insulation breakdown) caused by displacement current becomes smaller than the HVIC. Thus, not only is it possible to achieve reduction in mounting area in the IPM and miniaturization of the IPM with an inexpensive configuration but also it is possible to prevent noise resistance of the HVIC from deteriorating.

Note that as a comparative example to be compared with the present embodiment, a mode is conceivable in which not only are a control chip 41 and semiconductor chips 30A[k] arranged on the same die pad but also the anodes of BSDs are arranged on, instead of the front surface side of the semiconductor chips, the back surface side of the semiconductor chips and a charging current route is set in the vertical direction (i.e., the thickness direction of the semiconductor chips).

Although in the comparative example, potential of the die pad is required to be set to a Vcc potential, the back surface of an HVIC that is arranged on the same die pad as the BSDs is a P-type semiconductor substrate (Psub). Thus, the Psub of the HVIC is required to be isolated from the Vcc potential, and it is thus required to apply an insulating adhesive agent on the back surface of the HVIC. In this configuration, when the back surface of the HVIC is insulated by an insulating adhesive agent or the like, there is a possibility that when dV/dt noise is input to a high-side region of the HVIC, generation of displacement current due to a product of junction capacitance Ch between an N well and the Psub and dV/dt causes Psub (substrate) potential to rise to several hundred volts and to exceed dielectric withstand voltage of the insulating adhesive agent on the back surface of the HVIC and the Psub is short-circuited to Vcc. Further, it is conceivable that generated carriers cannot be extracted in the vertical (back surface) direction in the high-side region of the HVIC and a malfunction is caused to easily occur.

In contrast, in the semiconductor device 100A of the present embodiment, the ground voltage (GND) is supplied to the die pad 64 and the back surface of the control chip 41, which is an HVIC, is fixed to the die pad 64 via the conductive adhesive agent 71. Because of this configuration, in the semiconductor device 100A, with regard to the control chip 41, a short circuit between the Psub and Vcc as described in the comparative example can be prevented. Further, since in the semiconductor device 100A, the ground voltage (GND) is supplied from the die pad 64 to the control chip 41 via the conductive adhesive agent 71, a possibility that generated carriers being unable to be extracted in the vertical (back surface) direction in the high-side regions causes a malfunction to occur can be reduced.

As described in the foregoing, the semiconductor device 100A according to the first embodiment of the present disclosure includes a plurality of power semiconductor elements (for example, the drive chips 21[k] and the drive chips 22[k]) and the control chip 41 including a plurality of terminals including a first terminal (for example, the voltage terminal Hc) and a plurality of second terminals (for example, the power supply terminals Hb[k]) and configured to control each of the plurality of power semiconductor elements, using a corresponding one of the power supply voltages Vb[k] supplied to a corresponding one of the plurality of second terminals. The semiconductor device 100A also includes a first conductor (for example, the lead Rd63 and the connection terminal Tc_H) for supplying a predetermined control voltage Vcc to the first terminal, a plurality of first wirings (for example, the wires Qb[k]) each of which is individually connected to a corresponding one of the plurality of second terminals and is for supplying a corresponding one of the power supply voltages Vb[k] to the corresponding one of the plurality of the second terminals, the die pad 64 on which the control chip 41 is arranged, and the semiconductor chips 30A[k] each of which includes a corresponding one of diodes D[k] that is used for the bootstrap operation to generate a corresponding one of the power supply voltages Vb[k].

The semiconductor chips 30A[k] include, for example, the semiconductor chip 30A[U] including the diode D[U], the semiconductor chip 30A[V] including the diode D[V], and the semiconductor chip 30A[W] including the diode D[W]. Each of the semiconductor chips 30A[k] is fixed to the die pad 64 by the insulating adhesive agent 72. The die pad 64 is connected to a terminal (for example, the connection terminal Tg) to which a reference voltage (for example, the ground voltage (GND)) is supplied.

Because of this configuration, the semiconductor device 100A is capable of, while preventing noise resistance from deteriorating, achieving miniaturization.

Note that although in the first embodiment, a case where the control chip 41 is a 3ch-HVIC in which three phases are integrated into one chip was described, the case is only an example. The control chip 41 may be composed of three chips each of which is a single-phase HVIC (i.e., three chips in total, namely an HVIC for driving the U-phase, an HVIC for driving the V-phase, and an HVIC for driving the W-phase). Further, the control chip 41, which is an HVIC, and the control chip 42, which is an LVIC, may be integrated into one chip. Such a configuration may be applied to not only the first embodiment but also a second embodiment, which will be described later.

### B: Second Embodiment

In the above-described first embodiment, it was described that one semiconductor chip 30A[U] including the diode D[U], which is a BSD for the U-phase, one semiconductor chip 30A[V] including the diode D[V], which is a BSD for the V-phase, and one semiconductor chip 30A[W] including the diode D[W], which is a BSD for the W-phase, are arranged on the die pad 64.

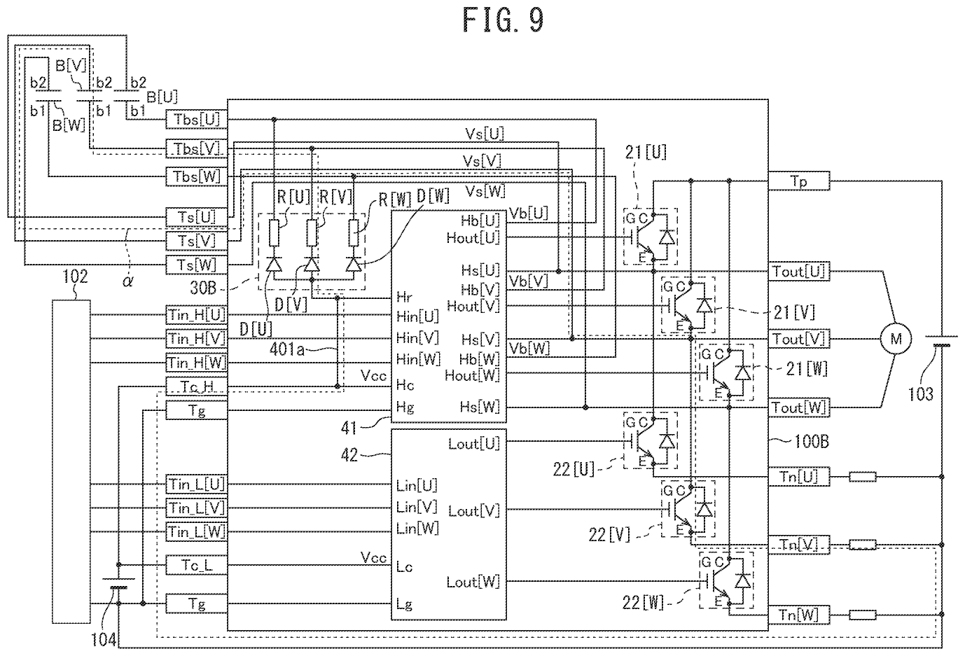

However, embodiments of the present disclosure are not limited to the configuration. In an embodiment of the present disclosure, a semiconductor chip 30A[U] including a diode D[U], a semiconductor chip 30A[V] including a diode D[V], and a semiconductor chip 30A[W] including a diode D[W] may be integrated into one chip. A semiconductor chip 30B including a plurality of diodes D[k] and a control chip 41 that is an HVIC may be arranged on the same die pad 64. Such a mode of embodiment will be described as the second embodiment, using FIGS. 9 to 12.

Note that in the second embodiment, with respect to elements the functions of which are the same as those of the elements of the semiconductor device according to the first embodiment, reference signs used in the description of the semiconductor device of the first embodiment will also be used and a detailed description thereof will be appropriately omitted.

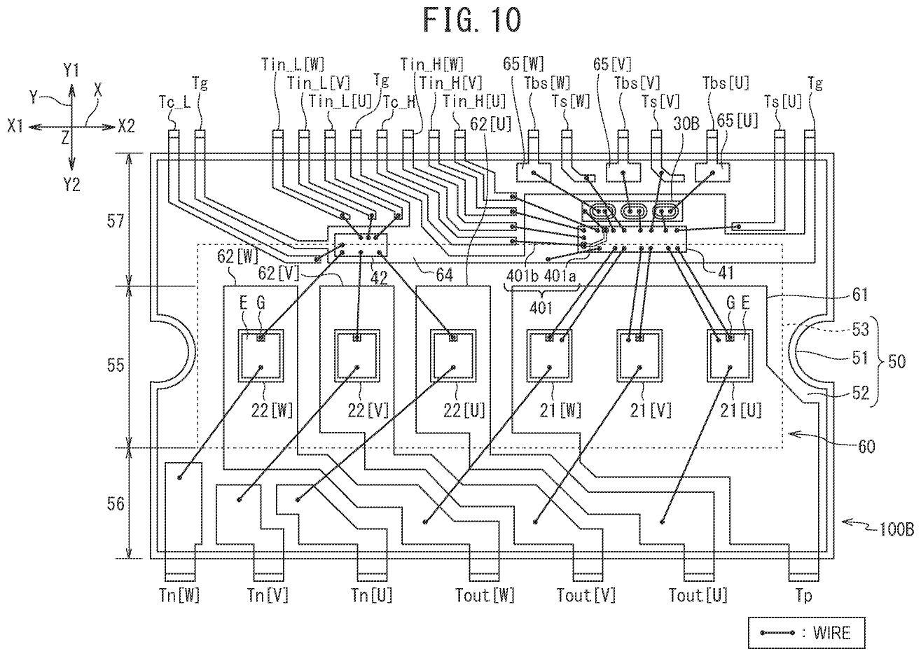

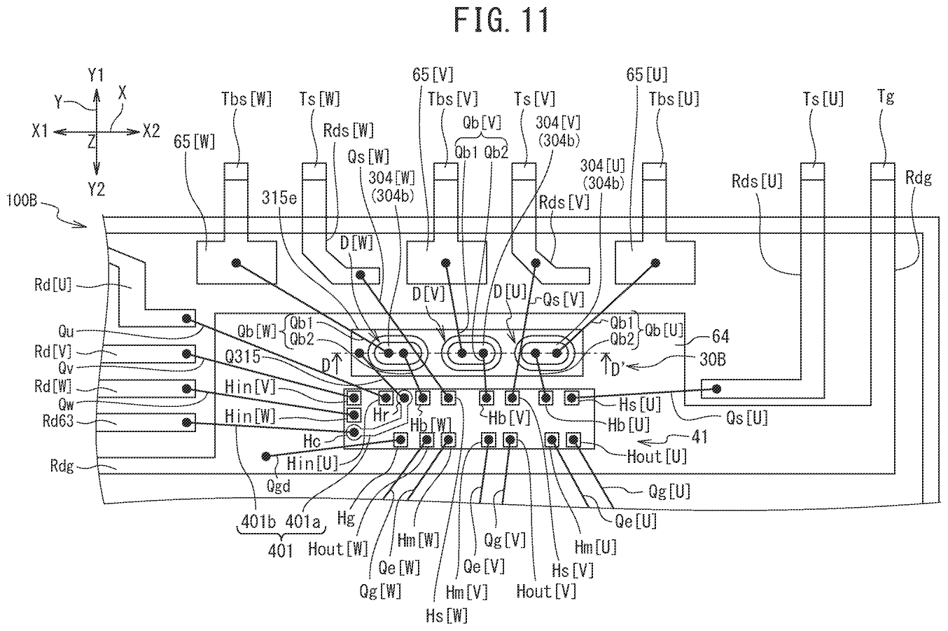

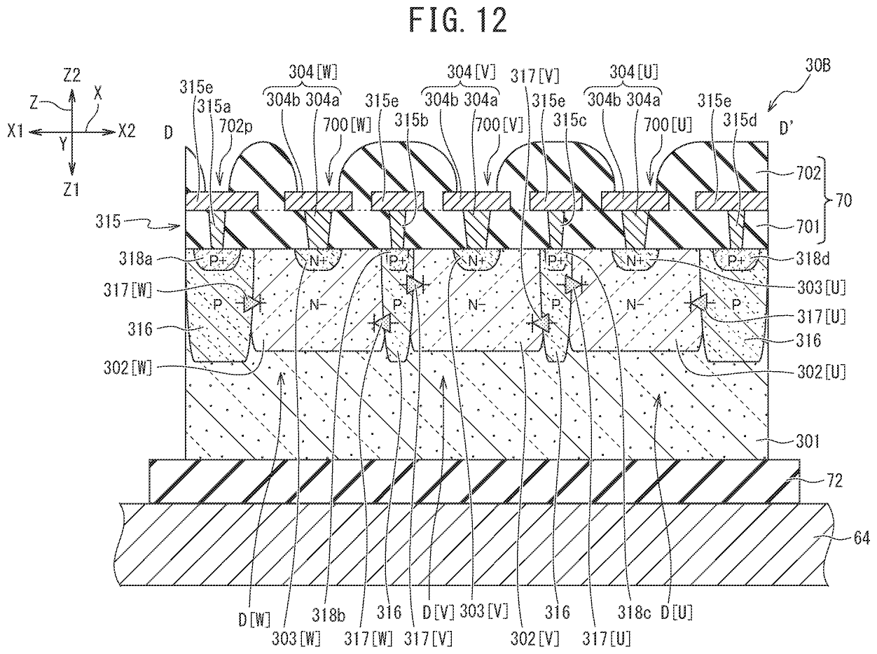

FIG. 9 is a circuit diagram illustrative of an electrical configuration of a semiconductor device 100B according to the second embodiment of the present disclosure. FIG. 10 is a layout diagram illustrative of an arrangement of respective elements included in the semiconductor device 100B. FIG. 11 is a layout diagram illustrative of a vicinity of the semiconductor chip 30B and high-potential-side drive chips 21[k] included in the semiconductor device 100B in an enlarged manner. FIG. 12 is a cross-sectional view of the semiconductor chip 30B taken along the line D-D′ illustrated in FIG. 11. The semiconductor device 100B according to the present embodiment has a feature that one semiconductor chip 30B includes a plurality of diodes D[k] used for bootstrap operation and charge routes are formed in directions parallel or substantially parallel with a front surface of a semiconductor substrate 301 (for example, lateral directions).

As exemplarily illustrated in FIG. 9, the semiconductor device 100B according to the second embodiment, as with the semiconductor device 100A according to the first embodiment, includes the control chip 41 that is configured to control each of the drive chips 21[k], using a corresponding one of power supply voltages Vb[k] supplied to a corresponding one of power supply terminals Hb[k], a lead Rd63 (not illustrated inf FIG. 9, see FIG. 11) for supplying control voltage Vcc to a voltage terminal Hc, and wires Qb[k] (not illustrated in FIG. 9, see FIG. 11) each of which is individually connected to a corresponding one of the power supply terminals Hb[k] and is for supplying a corresponding one of the power supply voltages Vb[k] to a corresponding one of the power supply terminals Hb[k]. The semiconductor device 100B also includes the semiconductor chip 30B that is used for bootstrap operation to generate the power supply voltages Vb[k] and includes the diodes D[k] the number of which is the same as the number of the power supply voltages Vb[k].

As exemplarily illustrated in FIG. 10, the die pad 64 disposed in the semiconductor device 100B is formed in such a manner as to spread beneath the control chips 41 and 42 and the semiconductor chip 30B. The control chips 41 and 42 and the semiconductor chip 30B are bonded on the die pad 64. That is, the control chips 41 and 42 and the semiconductor chip 30B are bonded to a front surface of the die pad 64. For mounting of the semiconductor chip 30B, an insulating adhesive agent is used. Therefore, the under surface of the semiconductor chip 30B and the die pad 64 are electrically insulated from each other. Further, for mounting of the control chip 41, a conductive adhesive agent is used. Therefore, the under surface of the control chip 41 and the die pad 64 are electrically connected to each other.

Next, a specific configuration of the semiconductor chip 30B will be described using FIG. 12 while referring to FIGS. 9 to 11. As exemplarily illustrated in FIG. 12, the semiconductor chip 30B includes a plurality of (three in the present embodiment) diodes D[k]. The diodes D[k] include the P-type semiconductor substrate 301. Each of the diodes D[k] includes a corresponding one of N-type N⁻ diffusion layers 302[k] that are formed side by side at a predetermined interval in a front surface layer of the semiconductor substrate 301. The diodes D[k] include a P-type diffusion layer 316 that is formed in an area in the front surface layer of the semiconductor substrate 301 in which the N⁻ diffusion layers 302[k] are not formed. In FIG. 12, to facilitate understanding, pn junction portions 317[k] each of which is formed at a junction portion between a corresponding one of the N⁻ diffusion layers 302[k] and the diffusion layer 316 are illustrated by schematic symbols of diodes.

The diffusion layer 316 forms anode regions of the diodes D[k], and each of the N⁻ diffusion layers 302[k] forms a cathode region of a corresponding one of the diodes D[k]. Note that each of the N⁻ diffusion layers 302[k] also serves as a corresponding one of resistance elements R[k]. Although the semiconductor substrate 301 also functions as the anode regions of the diodes D[k], portions through which current mainly flows are the junction portions between the N⁻ diffusion layers 302[k] and the diffusion layer 316.

A pn junction portion 317[U] of the diode D[U] is formed at a junction portion between the diffusion layer 316 and the N⁻ diffusion layer 302[U]. A pn junction portion 317[V] of the diode D[V] is formed at a junction portion between the N⁻ diffusion layer 302[V] and the diffusion layer 316. A pn junction portion 317[W] of the diode D[W] is formed at a junction portion between the N⁻ diffusion layer 302[W] and the diffusion layer 316.

As exemplarily illustrated in FIG. 12, the semiconductor chip 30B includes the P-type diffusion layer 316 that is formed in an area in the front surface layer of the semiconductor substrate 301 in which the N⁻ diffusion layers 302[k] are not formed. Therefore, each of the N⁻ diffusion layers 302[k] is formed in an island shape as viewed in plan, and the diffusion layer 316 is formed in the surroundings of the N⁻ diffusion layers 302[k]. Although, in FIG. 12, portions of the diffusion layer 316 at both ends and portions of the diffusion layer 316 on both sides of the N⁻ diffusion layers 302[k] are formed with different widths, the portions may be formed with the same width.

The diffusion layer 316 is formed by ion-implanting, for example, boron as a P-type impurity in a predetermined region on the front surface of the semiconductor substrate 301 and activating a site at which the P-type impurities are ion-implanted. The diffusion layer 316 is, for example, formed with a depth deeper than depths of the N⁻ diffusion layers 302[k].

The semiconductor chip 30B includes P⁺ diffusion layers 318a, 318b, 318c, and 318d that are formed in portions of a front surface of the diffusion layer 316. The P⁺ diffusion layers 318a, 318b, 318c, and 318d have higher impurity concentrations than the diffusion layer 316. The P⁺ diffusion layers 318a, 318b, 318c, and 318d, for example, have the same impurity concentration as N⁺ diffusion layers 303[k].

The P⁺ diffusion layers 318a, 318b, 318c, and 318d are formed with depths shallower than a depth of the diffusion layer 316 in predetermined regions on the front surface of the diffusion layer 316 by ion-implanting, for example, boron as a P-type impurity and activating sites at which the P-type impurities are ion-implanted.

The P⁺ diffusion layer 318a is formed in a region that is a portion of the front surface of the diffusion layer 316 and is located between a sidewall of the semiconductor substrate 301 and the N⁻ diffusion layer 302[W]. The P⁺ diffusion layer 318b is formed in a region that is a portion of the front surface of the diffusion layer 316 and is located between the N⁻ diffusion layer 302[W] and the N⁻ diffusion layer 302[V]. The P⁺ diffusion layer 318c is formed in a region that is a portion of the front surface of the diffusion layer 316 and is located between the N⁻ diffusion layer 302[V] and the N⁻ diffusion layer 302[U]. The P⁺ diffusion layer 318d is formed in a region that is a portion of the front surface of the diffusion layer 316 and is located between the N⁻ diffusion layer 302[U] and another sidewall of the semiconductor substrate 301.

As exemplarily illustrated in FIG. 12, the semiconductor chip 30B includes cathodes 304[k] each of which is formed on a corresponding one of the N⁻ diffusion layers 302[k] and is electrically connected to a corresponding one of the power supply terminals Hb[k] via a corresponding one of the wires Qb[k] (not illustrated in FIG. 12, see FIG. 11). Each of the cathodes 304[k] is formed in contact with a corresponding one of the N⁺ diffusion layers 303[k].

Since the cathodes 304[k] in the present embodiment have the same configurations as the cathodes 304[k] in the first embodiment (see FIG. 5), a description thereof will be omitted. Each of the cathodes 304[k] is formed with a conductive plug 304a in contact with a corresponding one of the N⁺ diffusion layers 303[k]. Thus, each of the cathodes 304[k] and a corresponding one of the N⁺ diffusion layers 303[k] are ohmic-connected. This configuration also enables reduction in contact resistance between each of the cathodes 304[k] and a corresponding one of the N⁺ diffusion layers 303[k] to be achieved in the present embodiment.

As exemplarily illustrated in FIG. 12, the semiconductor chip 30B includes an anode 315 that is formed on the diffusion layer 316 and is electrically connected to the lead Rd63 (not illustrated in FIG. 12, see FIG. 11) via a wiring member 401 (not illustrated in FIG. 12, see FIG. 11).

More specifically, the anode 315 includes conductive plugs 315a, 315b, 315c, and 315d that are formed in contact with the P⁺ diffusion layers 318a, 318b, 318c, and 318d, respectively, and an electrode plate 315e that is formed in contact with the conductive plugs 315a, 315b, 315c, and 315d. The conductive plug 315a is formed in contact with the P⁺ diffusion layer 318a. The conductive plug 315b is formed in contact with the P⁺ diffusion layer 318b. The conductive plug 315c is formed in contact with the P⁺ diffusion layer 318c. The conductive plug 315d is formed in contact with the P⁺ diffusion layer 318d. Thus, the anode 315 and the P⁺ diffusion layers 318a, 318b, 318c, and 318d are in ohmic contact. This configuration enables reduction in contact resistance between the anode 315 and the P⁺ diffusion layers 318a, 318b, 318c, and 318d to be achieved.

As exemplarily illustrated in FIG. 11, the electrode plate 315e is electrically connected to a relay terminal Hr of the control chip 41 by a wire Q315. One end of the wire Q315 is bonded to a portion of a front surface of the electrode plate 315e that is exposed in an opening 702p (see FIG. 12) formed in an insulating film 70 (not illustrated in FIG. 11, see FIG. 12). The other end of the wire Q315 is bonded to a front surface of the relay terminal Hr. The relay terminal Hr is formed at one end of a relay pattern 401a. At the other end of the relay pattern 401a, the voltage terminal Hc is formed. The voltage terminal He and the lead Rd63 are connected to each other by a wire 401b. The lead Rd63 is connected to a connection terminal Tc_H (see FIG. 10) to which the control voltage Vcc is input from an external power supply 104 (see FIG. 9). Thus, to the anode 315, the control voltage Vcc is supplied via the connection terminal Tc_H, the lead Rd63, the wiring member 401 (i.e., the wire 401b and the relay pattern 401a), and the wire Q315.

Returning to FIG. 12, the semiconductor chip 30B has a surface on the opposite side to the front surface of the semiconductor substrate 301 (i.e., the back surface) adhered to the die pad 64 by an insulating adhesive agent 72. To a body of the semiconductor substrate 301 of the semiconductor chip 30B, the control voltage Vcc is supplied from the anode 315. On the other hand, the die pad 64 is connected to connection terminals Tg to which a ground voltage is supplied via leads Rdg. Thus, to the die pad 64, the ground voltage is supplied via the connection terminals Tg and the leads Rdg.

Therefore, voltage supplied to the semiconductor substrate 301 of the semiconductor chip 30B and voltage supplied to the die pad 64 are different from each other. However, since the semiconductor substrate 301 of the semiconductor chip 30B and the die pad 64 are insulated from each other by the insulating adhesive agent 72, the connection terminal Tc_H and the connection terminals Tg are prevented from being short-circuited.

Next, advantageous effects of the semiconductor device 100B will be described using FIGS. 9 to 12.

As exemplarily illustrated in FIGS. 9 to 12, the semiconductor chip 30B in the present embodiment has a structure in which the diode D[U] for the bootstrap operation of the U-phase, the diode D[V] for the bootstrap operation of the V-phase, and the diode D[W] for the bootstrap operation of the W-phase are integrated into one chip.

As exemplarily illustrated in FIG. 12, the diode D[U], the diode D[V], and the diode D[W] formed in the semiconductor chip 30B include the pn junction portions 317[U], 317[V], and 317[W] that form pn junctions in directions orthogonal to the thickness direction of the semiconductor substrate 301 (the X-axis direction illustrated in FIG. 12), respectively. The P-type semiconductor sides of the pn junction portions 317(U), 317[V], and 317[W] are formed by and share with one another the diffusion layer 316. On the other hand, the N-type semiconductor sides of the pn junction portions 317[U], 317[V], and 317[W] are formed by the N⁻ diffusion layers 302[U], 302[V], and 302[W], respectively. The N⁻ diffusion layers 302[U], 302[V], and 302[W] are separated from each other by the P-type diffusion layer 316.

The anode 315 connected to the diode D[U], the diode D[V], and diode D[W] is arranged above the semiconductor substrate 301 and is shared by the diode D[U], the diode D[V], and diode D[W]. On the other hand, the cathodes 304[U], 304[V], and 304[W] that are connected to the diode D[U], the diode D[V], and diode D[W] are formed in contact with the N⁻ diffusion layers 302[U], 302[V], and 302[W], respectively, and are disposed separated from each other.

The diffusion layer 316 forms the anode regions of the diodes D[k]. The diode D[U] forms the pn junction portion 317[U] in conjunction with the N⁻ diffusion layer 302[U] and a portion of the diffusion layer 316 arranged around the N⁻ diffusion layer 302[U]. The diode D[V] forms the pn junction portion 317[V] in conjunction with the N⁻ diffusion layer 302[V] and a portion of the diffusion layer 316 arranged around the N⁻ diffusion layer 302[V]. The diode D[W] forms the pn junction portion 317[W] in conjunction with the N⁻ diffusion layer 302[W] and a portion of the diffusion layer 316 arranged around the N⁻ diffusion layer 302[W]. Further, the diode D[U], the diode D[V], and the diode D[W] form pn junctions in conjunction with the N⁻ diffusion layers 302[U], 302[V], and 302[W] in the thickness direction of the semiconductor substrate 301 (the Z-axis direction illustrated in FIG. 12), respectively.

It is now assumed that the power supply voltage on the high potential side of an external power supply 103 is, for example, 200 V and the control voltage Vcc of the external power supply 104 is, for example, 15 V. Further, a case where the drive chip 21[U], the drive chip 22[V], and the drive chip 22[W] are in the ON state and the drive chip 22[U], the drive chip 21[V], and the drive chip 21[W] are in the OFF state is considered.

In this case, voltage at a connection terminal Tout[U] is 200 V, and 200 V is applied to the cathode 304[U] of the semiconductor chip 30B. Voltages at a connection terminal Tout[V] and a connection terminal Tout[W] are the ground voltage, and the ground voltage is applied to the cathode 304[V] and the cathode 304[W] of the semiconductor chip 30B. Further, 15 V is applied to the semiconductor substrate 301 and the diffusion layer 316.

Thus, the diode D[V] and the diode D[W] charge a capacitance element B[V] and a capacitance element B[W], respectively.

On the other hand, regarding the diode D[U], since reverse bias is applied to the pn junction between the semiconductor substrate 301 and the N⁻ diffusion layer 302[U] and the pn junction portion 317[U], depletion layers expand from the pn junction and the pn junction portion 317[U] to a portion of the diffusion layer 316 arranged around the N⁻ diffusion layer 302[U], the semiconductor substrate 301, and the N⁻ diffusion layer 302[U].

The widths and impurity concentration of the diffusion layer 316 are set in such a manner that the depletion layer expanding in a portion of the diffusion layer 316 around the N⁻ diffusion layer 302[U] does not reach the N⁻ diffusion layer 302[V] of the diode D[V] and other depletion layers do not reach the P⁺ diffusion layer 318c, the P⁺ diffusion layer 318d, and the N⁺ diffusion layer 303[U].

By setting the diffusion layer 316 in this way, the N⁻ diffusion layers 302[U], 302[V], and 302[W] are separated from each other by the P-type diffusion layer 316.

To the P-type semiconductor side of the pn junction portion 317[k] of each of the diodes D[k] (i.e., the diffusion layer 316), the common control voltage Vcc is supplied via the anode 315, the wire Q315, the wiring member 401, the lead Rd63, and the connection terminal Tc_H (see FIG. 10).

On the other hand, to the N-type semiconductor side of the pn junction portion 317[k] of each of the diodes D[k] (i.e., the N⁻ diffusion layer 302[k]), voltage matching the bootstrap operation is independently supplied via a corresponding one of the N⁻ diffusion layers 303[k], a corresponding one of the cathodes 304[k], a wire wiring Qb2 of a corresponding one of the wires Qb[k], a corresponding one of connection pads 65[k], and a corresponding one of connection terminals Tbs[k]. Thus, even when the semiconductor chip 30B has a structure in which the three diodes D[k] for the bootstrap operation of the U-phase, the V-phase, and the W-phase are integrated into one chip, the semiconductor chip 30B is capable of forming a charge route α (see FIG. 9) to charge a capacitance element B[k] in the bootstrap operation with respect to each of the U-phase, the V-phase, and the W-phase.

Further, to the electrode plate 315e, the control voltage Vcc is supplied. Further, the electrode plate 315e also exists over boundaries between the N⁻ diffusion layers 302[k] and the diffusion layer 316. Thus, the electrode plate 315e functions as a field plate, as a result of which improvement in withstand voltage of the semiconductor chip 30B can be achieved.

As described above, since the semiconductor device 100B according to the present embodiment includes the semiconductor chip 30B in which the three diodes D[k] for bootstrap operation are integrated into one chip, compared with the semiconductor device 100A according to the first embodiment (see FIGS. 1 to 8) including the three semiconductor chips 30A[U], 30A[V], and 30A[W] that individually have diodes for bootstrap operation for the U-phase, the V-phase, and the W-phase, respectively, the semiconductor device 100B enables space-saving of mounting area and reduction in the number of components of the semiconductor chip 30B for bootstrap operation to be achieved. Because of this capability, it is possible to achieve a reduction in external dimensions of the semiconductor device 100B.

As described in the foregoing, the semiconductor device 100B according to the second embodiment of the present disclosure includes a plurality of power semiconductor elements (for example, the drive chips 21[k] and the drive chips 22[k]) and the control chip 41 including a plurality of terminals including a first terminal (for example, the voltage terminal Hc) and a plurality of second terminals (for example, the power supply terminals Hb[k]) and configured to control each of the plurality of power semiconductor elements, using a corresponding one of the power supply voltages Vb[k]supplied to a corresponding one of the plurality of second terminals. The semiconductor device 100B also includes a first conductor (for example, the lead Rd63 and the connection terminal Tc_H) for supplying a predetermined control voltage Vcc to the first terminal, a plurality of first wirings (for example, the wires Qb[k]) each of which is individually connected to a corresponding one of the plurality of second terminals and is for supplying a corresponding one of the power supply voltages Vb[k] to the corresponding one of the plurality of the second terminals, the die pad 64 on which the control chip 41 is arranged, and the semiconductor chip 30B that includes the diodes D[k] each of which is used for the bootstrap operation to generate a corresponding one of the power supply voltages Vb[k].

The semiconductor chip 30B includes, for example, the diodes D[U], D[V], and D[W]. The semiconductor chip 30B has a structure in which the diodes D[U], D[V], and D[W] are integrated into one chip. The semiconductor chip 30B is fixed to the die pad 64 by the insulating adhesive agent 72. The die pad 64 is connected to a terminal (for example, the connection terminals Tg) to which a reference voltage (for example, the ground voltage (GND)) is supplied.

Because of this configuration, the semiconductor device 100B is capable of, while preventing noise resistance from deteriorating, achieving miniaturization. Further, the semiconductor device 100B, by integrating the diodes D[U], D[V], and D[W] into one chip, is capable of achieving further miniaturization and cost reduction.

### REFERENCE SIGNS LIST

21, 22 Drive chip
30A[k] (k=U, V, or W), 30B Semiconductor chip
41, 42 Control chip
50 Casing
51 Resin case
52 Support plate
53 Sealing resin
55 Element region
56 Terminal region
57 Control region
60 Lead frame
61, 62, 64 Die pad
65[k] (k=U, V, or W) Connection pad
70, 520, 701 Insulating film
71 Conductive adhesive agent
72 Insulating adhesive agent
100A, 100B Semiconductor device
102 Control device
103, 104 External power supply
301 Semiconductor substrate
302, 302[k] (k=U, V, or W) N⁻ diffusion layer
303, 303[k] (k=U, V, or W) N⁺ diffusion layer
304a, 315a, 315b, 315c, 315d Conductive plug
304b Electrode pad
315[k] (k=U, V, or W) Anode
317[k] (k=U, V, or W) pn junction portion
316 Diffusion layer
318a, 318b, 318c, 318d P⁺ diffusion layer
315e Electrode plate
401 Wiring member
401a Relay pattern
401b Wire
700[k] (k=U, V, or W), 702p1, 702p2 Opening
702 Protective film
B Capacitance element
b1 First electrode
b2 Second electrode
C, E Main electrode
D Diode
G Control electrode
H, L Terminal
Hb Power supply terminal
Hc, Lc Voltage terminal
Hg, Lg Ground terminal
Hin Input terminal
Hm[k] (k=U, V, or W) Middle terminal
Hout[k] (k=U, V, or W) Output terminal
Hr Relay terminal
Hs[k] (k=U, V, or W) Power supply terminal
Lin[k] (k=U, V, or W) Input terminal
Lout[k] (k=U, V, or W) Output terminal
M Motor
Q315, Q316, Q317, Qb[k] (k=U, V, or W), Qc, Qdg, Qe, Qg,
Qgd, Qs, Qu, Qv, Qw Wire
Qb1, Qb2 Wire wiring
Rs[k] (k=U, V, or W) Resistance element
Rd[k] (k=U, V, or W), Rd63, Rdg, Rds[k] (k=U, V, or W) Lead
T, Tbs[k] (k=U, V, or W), Tc_H, Tc_L, Tg, Tin_H[k] (k=U, V, or W), Tin_L[(k] (k=U, V, or W), Tn[k] (k=U, V, or W), Tout[k] (k=U, V, or W), Tp, Ts[k] (k=U, V, or W)
Connection terminal
Vb[k] (k=U, V, or W) Power supply voltage
Vcc Control voltage
Vs Power supply voltage
α Charge route

1. A semiconductor device comprising:
a plurality of power semiconductor elements;
a control chip including a plurality of terminals including a first terminal and a plurality of second terminals and configured to control the plurality of power semiconductor elements, using power supply voltage supplied to the plurality of second terminals;
a first conductor for supplying a predetermined control voltage to the first terminal;
a plurality of first wirings individually connected to the plurality of second terminals and configured to supply the power supply voltage to the plurality of second terminals;
a die pad on which the control chip is arranged; and
a semiconductor chip including a diode used for bootstrap operation to generate the power supply voltage,
wherein
the semiconductor chip is fixed to the die pad by an insulating material, and
the die pad is connected to a terminal to which a reference voltage is supplied.

2. The semiconductor device according to claim 1, wherein the reference voltage is a ground voltage.

3. The semiconductor device according to claim 1, wherein the control chip is fixed to the die pad by a conductive material.

4. The semiconductor device according to claim 1 further comprising
a second wiring connected to the first conductor,
wherein the semiconductor chip includes:
a semiconductor substrate of a first conductivity type;
a first semiconductor layer of the first conductivity type formed in a front surface layer of the semiconductor substrate;
a second semiconductor layer of a second conductivity type formed in a region in the front surface layer of the semiconductor substrate in which the first semiconductor layer is not formed and constituting the diode in conjunction with the first semiconductor layer;
an anode electrically connected to the first conductor via the second wiring and bonded to the first semiconductor layer; and
a cathode electrically connected to one of the second terminals via one of the first wirings and bonded to the second semiconductor layer.

5. The semiconductor device according to claim 4, wherein
the control chip includes a relay terminal electrically connected to the anode in the plurality of terminals, and
the second wiring includes a relay pattern connecting the relay terminal and the first terminal.

6. The semiconductor device according to claim 1, wherein the semiconductor chip includes:
a first semiconductor chip including a first diode used for bootstrap operation to generate a first AC phase of the power supply voltage;
a second semiconductor chip including a second diode used for bootstrap operation to generate a second AC phase of the power supply voltage; and
a third semiconductor chip including a third diode used for bootstrap operation to generate a third AC phase of the power supply voltage, and
each of the first semiconductor chip, the second semiconductor chip, and the third semiconductor chip is fixed to the die pad by the insulating material.

7. The semiconductor device according to claim 6 further comprising
a second wiring connected to the first conductor,
wherein each of the first semiconductor chip, the second semiconductor chip, and the third semiconductor chip includes:
a semiconductor substrate of a first conductivity type;
a first semiconductor layer of the first conductivity type formed in a front surface layer of the semiconductor substrate;
a second semiconductor layer of a second conductivity type formed in a region in the front surface layer of the semiconductor substrate in which the first semiconductor layer is not formed and constituting the diode in conjunction with the first semiconductor layer;
an anode electrically connected to the first conductor via the second wiring and bonded to the first semiconductor layer; and
a cathode electrically connected to one of the second terminals via one of the first wirings and bonded to the second semiconductor layer.

8. The semiconductor device according to claim 7 further comprising
a third wiring configured to electrically connect the anode included in the first semiconductor chip, the anode included in the second semiconductor chip, and the anode included in the third semiconductor chip to one another.

9. The semiconductor device according to claim 8, wherein the third wiring includes:
a first wire having one end bonded to the anode included in the first semiconductor chip and the other end bonded to the anode included in the second semiconductor chip; and
a second wire having one end bonded to the anode included in the second semiconductor chip and the other end bonded to the anode included in the third semiconductor chip.

10. The semiconductor device according to claim 1, wherein the semiconductor chip includes:
a semiconductor substrate of a first conductivity type;
a first diode formed in the semiconductor substrate and used for bootstrap operation to generate a first AC phase of the power supply voltage;
a second diode formed in the semiconductor substrate and used for bootstrap operation to generate a second AC phase of the power supply voltage; and
a third diode formed in the semiconductor substrate and used for bootstrap operation to generate a third AC phase of the power supply voltage.

11. The semiconductor device according to claim 2, wherein the semiconductor chip includes:
a semiconductor substrate of a first conductivity type;
a first diode formed in the semiconductor substrate and used for bootstrap operation to generate a first AC phase of the power supply voltage;
a second diode formed in the semiconductor substrate and used for bootstrap operation to generate a second AC phase of the power supply voltage; and
a third diode formed in the semiconductor substrate and used for bootstrap operation to generate a third AC phase of the power supply voltage.

12. The semiconductor device according to claim 2, wherein the control chip is fixed to the die pad by a conductive material.

13. The semiconductor device according to claim 2 further comprising
a second wiring connected to the first conductor,
wherein the semiconductor chip includes:
a semiconductor substrate of a first conductivity type;
a first semiconductor layer of the first conductivity type formed in a front surface layer of the semiconductor substrate;
a second semiconductor layer of a second conductivity type formed in a region in the front surface layer of the semiconductor substrate in which the first semiconductor layer is not formed and constituting the diode in conjunction with the first semiconductor layer;
an anode electrically connected to the first conductor via the second wiring and bonded to the first semiconductor layer; and
a cathode electrically connected to one of the second terminals via one of the first wirings and bonded to the second semiconductor layer.

14. The semiconductor device according to claim 2, wherein the semiconductor chip includes:
a first semiconductor chip including a first diode used for bootstrap operation to generate a first AC phase of the power supply voltage;
a second semiconductor chip including a second diode used for bootstrap operation to generate a second AC phase of the power supply voltage; and
a third semiconductor chip including a third diode used for bootstrap operation to generate a third AC phase of the power supply voltage, and
each of the first semiconductor chip, the second semiconductor chip, and the third semiconductor chip is fixed to the die pad by the insulating material.
